(19) United States
(12) Patent Application Publication
(10) Pub. No.: US 2025/0153709 A1
(43) Pub. Date: May 15, 2025

(54) DRIVING SIMULATION TRACKING

(71) Applicant: Pony.ai, Inc., Fremont, CA (US)

(72) Inventor: Zhen WU, San Jose, CA (US)

(21) Appl. No.: 18/505,794

(22) Filed: Nov. 9, 2023

(51) Int. Cl. B60W 30/08; B60W 60/00; G06V 20/58

(52) U.S. Cl. CPC B60W 30/08; G06V 20/58; B60W 60/0053

(57) ABSTRACT

A system includes one or more processors that obtain annotated frames of data. The annotated frames represent or are associated with a locomotive concept and include annotations. The system infers mappings between the annotated frames and concepts associated with locomotion of the vehicle. Each of the mappings correlates a subset of the annotated frames with a concept. The system receives a query for a particular concept, and retrieves, based on the mappings, a particular subset of the annotated frames correlated with the particular concept.

### BACKGROUND

The meteoric rise in deployment of autonomous or semi-autonomous vehicles has been a catalyst that has spurred efforts to improve their safety. By 2040, an anticipated 75 percent of vehicles will be autonomous or semi-autonomous, according to the Institute of Electrical and Electronics Engineers (IEEE). According to current estimates, approximately 9.1 autonomous or semi-autonomous vehicle crashes occur per million miles driven. Currently, extensive testing is conducted on autonomous and semi-autonomous vehicles to verify their safety. One mode of such testing involves simulations.

Simulations of driving scenarios encompass controlled, reproduced situations that mimic reality, which may otherwise be expensive, dangerous, or unrepeatable in reality. These simulations uncover potentially unsafe driving situations and measures to eliminate or reduce danger in these situations. However, due to complexity and permutations of driving scenarios, obtaining a sufficiently comprehensive set of driving scenarios remains a bottleneck, which limits a degree or extent of vehicle safety. Specifically, current driving scenarios may not incorporate possibilities such as different weather conditions, traffic conditions, driving behaviors, and other relevant considerations. Without such driving scenarios, vehicles may be ill-equipped to handle certain situations that have previously been overlooked. Yet another shortcoming is that driving scenarios are typically not stored in an organized, searchable manner, and are isolated from other driving scenarios, which limits usability and usefulness of current driving scenarios.

### SUMMARY

Described herein, in some examples, is a computing system that stores, organizes, and/or generates a set of searchable scenarios, such as driving scenarios. The computing system includes one or more processors that obtain or generate scenario data, which may include annotated or tagged (hereinafter “annotated”) data, which may be manifested as a dataset that includes textual data, frames of media data, and/or other data. The annotated data represents or is associated with locomotion of a vehicle (e.g., an ego vehicle). The annotated data contains annotations and may contain annotated frames. The computing system may include one or more processors; and a memory storing instructions that, when executed by the one or more processors, cause the system to perform certain operations. The operations may include inferring mappings or associations (hereinafter “mappings”) between the annotated data and concepts associated with locomotion of the vehicle. Each of the mappings correlates a subset of the annotated frames or the annotated data with a concept. The computing system may receive a query for a particular concept, and retrieve, based on the mappings, a particular subset of the annotated frames or scenario data correlated with the particular concept.

In some examples, the annotations are associated with one or more static entities, one or more dynamic entities, and/or one or more environmental conditions.

In some examples, the one or more dynamic entities include the vehicle and/or one or more other vehicles.

In some examples, the particular subset of the annotated data comprises a first frame and a second frame, the second frame comprising a static entity or a dynamic entity that is absent from the first frame. The first frame and the second frame may include media frames.

In some examples, the inferring of the mappings is based on relative positions between the annotations, for example, in a media frame.

In some examples, the inferring of the mappings is based on relative orientations between the annotations, for example, in a media frame.

In some examples, the inferring of the mappings is based on a driving signal of the vehicle or of an other vehicle.

In some examples, the inferring of the mappings is performed by a machine learning component, the machine learning component being trained over two stages, wherein a first stage is based on a first training dataset that correlates hypothetical annotated data to hypothetical concepts and a second stage is based on a second training dataset that comprises corrected hypothetical annotated data correlated to corrected hypothetical concepts.

In some examples, the annotated data comprises media files.

In some examples, the instructions further cause the system to perform: implementing or executing a testing simulation based on the inferred mappings, wherein the testing simulation comprises executing of a test driving operation involving a test vehicle that corresponds to the vehicle and monitoring one or more test vehicle attributes of the test vehicle.

In some examples, the inferring of the mappings is based on an ontological framework. The ontological framework defines linkages, relationships or patterns among the annotations (e.g., annotations that are commonly associated with other annotations), and also among the annotations and concepts associated with locomotion of the vehicle. For example, annotations of a driving vehicle and an opposite direction vehicle (e.g., traveling in an opposite direction as the driving vehicle) on a same lane may be linked to a concept of improper driving, wrong-way driving (WWD), or contraflow driving. As another example, annotations of a driving vehicle and a same direction vehicle on an adjacent lane, signaling, and/or increasing speed of the driving vehicle, may be linked to a concept of an attempted overtaking.

In some examples, a concept and/or an annotation is based on signaling of an external entity, and/or an inferred intent of the external entity. Thus, a scenario may be characterized based on signaling of an external entity, and/or an inferred intent of the external entity.

In some examples, a concept and/or an annotation is based on a presence of an external entity, the external entity including a non-terrestrial entity. Thus, a scenario may be characterized based on a presence of an external entity.

In some examples, a concept and/or an annotation is based on a presence of a non-vehicular entity. Thus, a scenario may be characterized based on a presence of a non-vehicular entity.

In some examples, a concept and/or an annotation is based on a behavior or a predicted behavior of an external entity. Thus, a scenario may be characterized based on a behavior or a predicted behavior of an external entity.

In some examples, a concept and/or an annotation is based on a presence or an absence of equipment or accessories attached to an external entity. Thus, a scenario may be characterized based on a presence or an absence of equipment or accessories attached to an external entity.

In some examples, the planned locomotive action is based on a road geometry. The generated output and/or the converted output indicates the road geometry. Thus, a scenario may be characterized based on a road geometry.

Various embodiments of the present disclosure provide a method implemented by a system as described above.

These and other features of the apparatuses, systems, methods, and non-transitory computer readable media disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for purposes of illustration and description only and are not intended as a definition of the limits of the invention.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the invention are utilized, and the accompanying drawings of which:

FIGS. 1A, 1B, 2A, 2B, 3A, 3B, 4A, 4B, 5A, 5B, 6A-6D, 7A, 7B, 8A, 8B, 8C, 9A, 9B, 10A, 10B, and 10C illustrate different examples of processing and characterization of scenario data using different factors in order to facilitate organization and retrieval of relevant scenario data.

FIGS. 1A and 1B illustrates an example implementation of a computing system that characterizes a scenario based on signaling and/or inferred behaviors of dynamic entities within a driving environment.

FIGS. 2A and 2B illustrates an example implementation of a computing system that characterizes a scenario based on signaling and/or inferred behaviors of dynamic entities within a driving environment, using multiple frames of data, multiple datasets, and/or multiple sources of data to elucidate an intent of a dynamic entity.

FIGS. 3A and 3B illustrates an example implementation of a computing system that characterizes a scenario based on types of dynamic entities.

FIGS. 4A and 4B illustrate an example implementation of a computing system that characterizes a scenario based on signaling from dynamic entities and/or based on types, categories, or classifications (hereinafter “types”) of dynamic entities, which may include non-terrestrial (e.g., non-land based) entities.

FIGS. 5A and 5B illustrate an example implementation of a computing system that characterizes a scenario based on types of dynamic entities, which may include non-vehicular entities such as pedestrians and/or animals.

FIGS. 6A-6D illustrate an example implementation of a computing system that characterizes a scenario based on entity behaviors, such as abnormal and/or unpredictable behaviors.

FIGS. 7A-7B illustrate an example implementation of a computing system that characterizes a scenario based on equipment attached to or associated with one or more dynamic entities.

FIGS. 8A-8C illustrate an example implementation of a computing system that characterizes a scenario based on loads associated with one or more dynamic entities.

FIGS. 9A, 9B, and 10A-10C illustrate an example implementation of a computing system that characterizes a scenario based on a road geometry.

FIGS. 11A, 11B, and 11C illustrate an implementation of an example interface through which scenario information may be retrieved and/or presented

FIG. 12 illustrates example implementations of training of machine learning components to infer characterizations of scenarios, and to perform other functions.

FIG. 13 illustrates an example implementation of downstream actions or processes.

FIG. 14 illustrates a flowchart which summarizes an exemplary process to process scenario data, characterize the scenario data, stored the characterized scenario data, and retrieve relevant scenario data.

FIG. 15 illustrates a block diagram of a computer system upon which any of the embodiments described herein may be implemented.

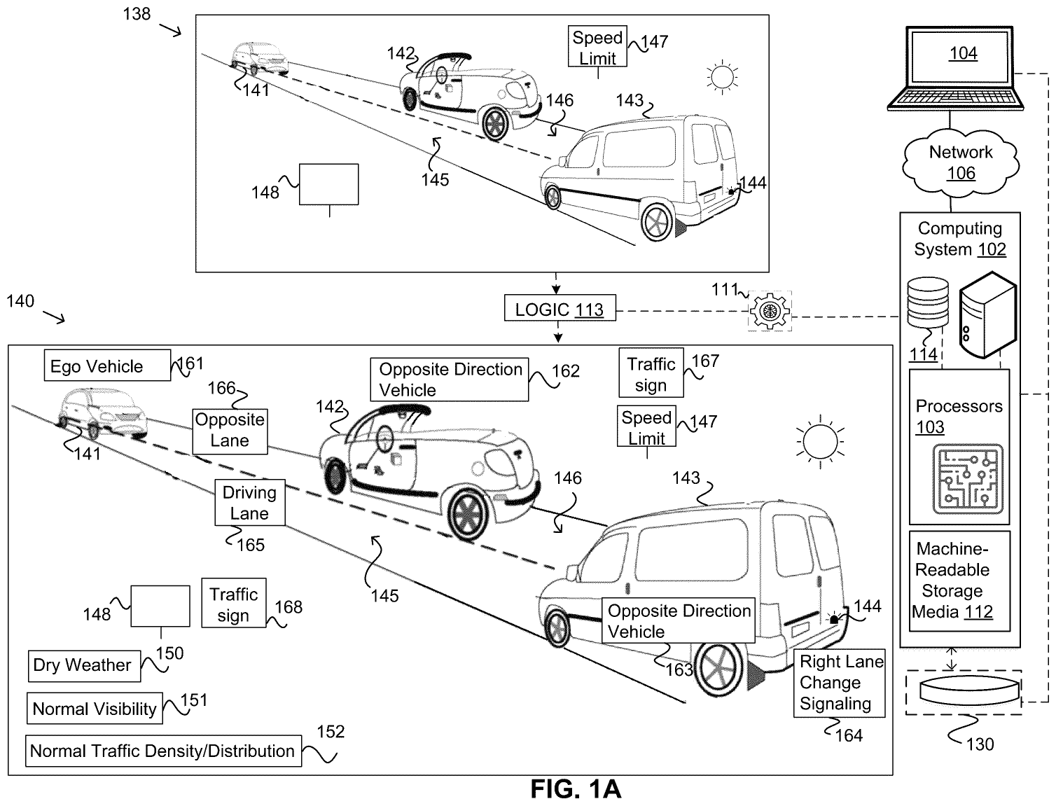

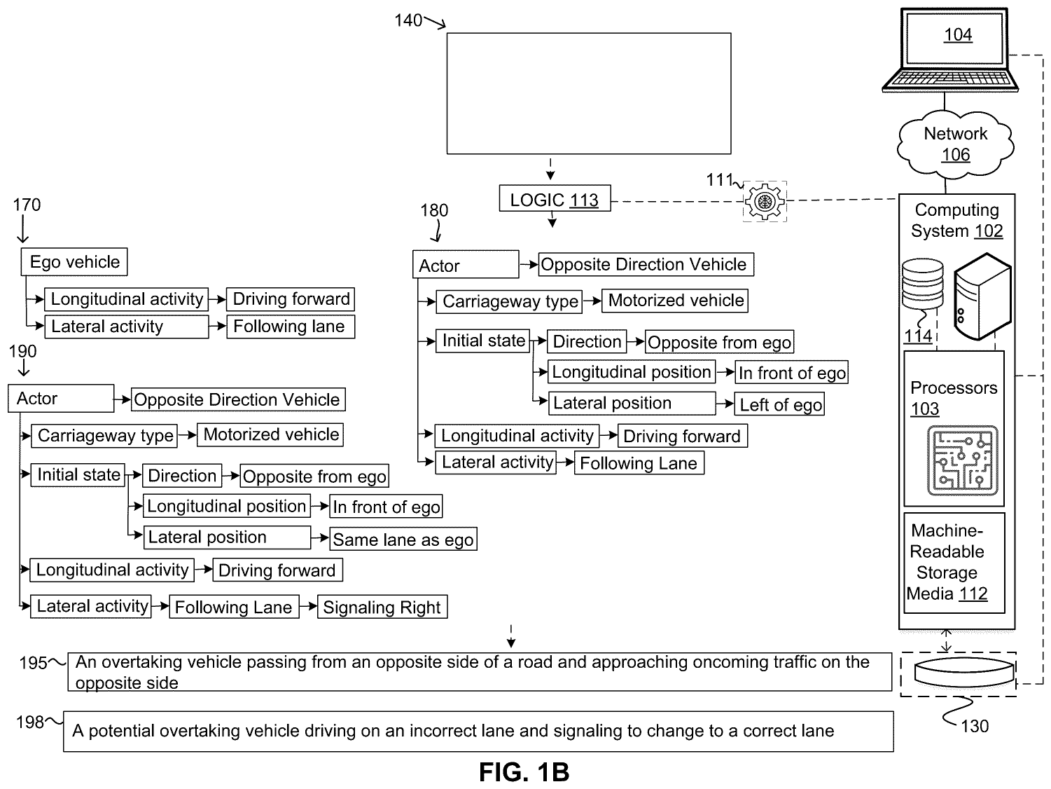

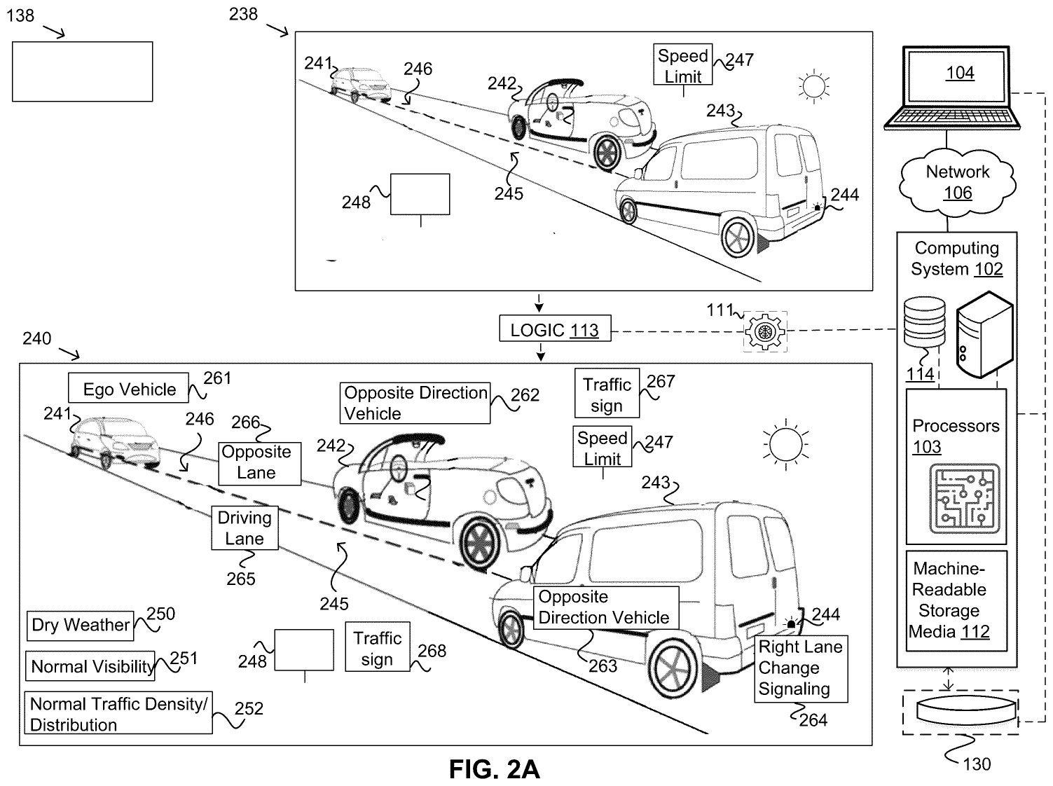

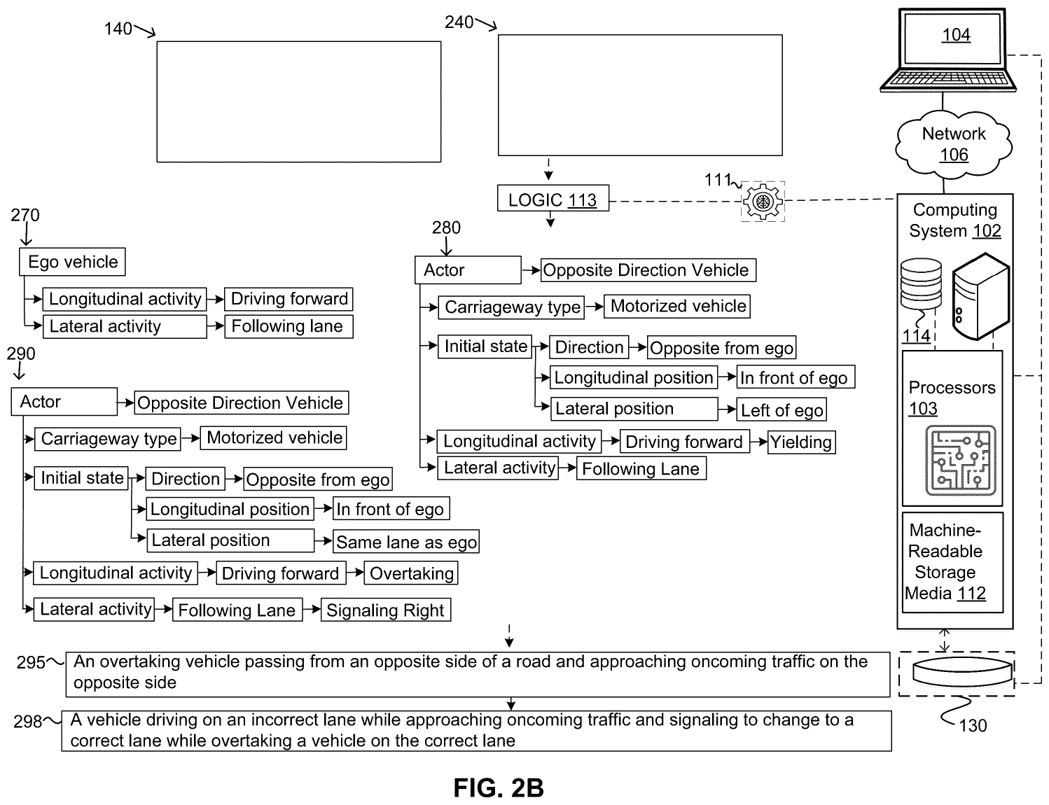

Principles from different figures may apply to, and/or be combined with other figures as suitable. For example, the principles illustrated in FIGS. 1A and 1B may be applied to and/or combined with principles from any of FIGS. 2A, 2B, 3A, 3B, 4A, 4B, 5A, 5B, 6A-6D, 7A, 7B, 8A, 8B, 8C, 9A, 9B, 10A-10C, 11A-11C, 12, 13, 14, and vice versa.

### DETAILED DESCRIPTION

Safety of vehicles, such as autonomous and semi-autonomous vehicles, remains a paramount concern before widespread deployment. A lack of adequate safety is a limiting factor that prevents regulatory approval or acceptance as well as driver or passenger acceptance and adoption of autonomous vehicles. To address and/or alleviate such safety concerns, these autonomous vehicles should undergo stringent testing under a comprehensive and diverse range of settings, situations, or scenarios (hereinafter “scenarios”). In order to conduct this testing in a systematic manner, these scenarios should be obtained or generated, stored, recorded, annotated, categorized, organized, stored, and/or tracked to facilitate scenario searching, retrieval, or mining. Testing results of the scenarios should also be stored and updated. For example, in order to sufficiently prepare an autonomous vehicle for a navigation concept such as one that includes maneuvering through a bend, different scenarios which include permutations or variations of maneuvering a bend should be tested.

Currently, implementations are limited to manual categorization, organization, and storage of driving scenarios, if they are even categorized or stored at all. Such manual processes result in a limited range of driving scenarios, as well as an increased possibility of erroneous scenarios. In addition, limitations of properly recording and organizing these driving scenarios may limit an ability to retrieve and track these driving scenarios for continuous improvement, expansions upon the driving scenarios, and analysis (e.g., exposure analysis). As a result, the gaps in current implementations do not sufficiently prepare a vehicle, such as an autonomous vehicle, for an entire gamut of driving scenarios that the vehicle may encounter.

Therefore, by generating, recording, organizing (e.g., cataloguing), and tracking a comprehensive set of scenarios, a computing system associated with the vehicles will recognize, predict, and respond to a comprehensive range of scenarios, which may include rare and/or complex scenarios. As a result, this enhanced computing system is a catalyst that would improve robustness of vehicle testing and validation, which in turn leads to safer vehicles and more streamlined regulatory approval processes.

The computing system may include or be associated with machine learning components such as a Large Language Model (LLM), to store, catalog, categorize, and retrieve scenarios, generate or predict new scenarios, and/or infer relationships, mappings, and/or patterns among the scenarios and/or among the scenarios and concepts associated with locomotion of a vehicle. Any operations attributed to the computing system may also be attributed to the machine learning components. These scenarios may be obtained and/or derived from sensor data, geospatial data such as map data, media data, and/or a text format. For example, the computing system may obtain and ingest scenario data, which may encompass sensor data from Lidar, camera, radar, inertial measurement units (IMUs), Global Positioning Systems (GPSs), other applicable sensors, and/or text data. The scenario data may include raw scenario data. The computing system may generate processed scenario data from the scenario data. In particular, the computing system may annotate the scenario data with semantics to indicate entities or features (hereinafter “entities”) such as dynamic entities and attributes thereof, static entities and attributes thereof, and an ego vehicle and attributes thereof. Dynamic entities may include other moving or potentially moving actors that are relevant to a navigation response of the ego vehicle. These other actors may include other vehicles (e.g., land vehicles or aerial vehicles), pedestrians, and/or animals. Meanwhile, static entities may include other stationary or likely stationary entities such as a road, road signs, traffic signals, barriers, lighting, shadows, and other environmental or weather conditions. The ego vehicle may include a vehicle that is making locomotive decisions and executing the locomotive decisions while responding to different stimuli associated with the entities.

The annotations may indicate relative positions of entities and/or distances among entities depicted in data, such as a media frame. The computing system may format, convert or organize (hereinafter “convert”) the annotations into a structured or organized format, or a data structure, such as a structured set of annotations. The structured set of annotations may include a hierarchical format. The computing system may convert or translate (hereinafter “translate”) the annotations and/or the structured format into one or more descriptions of a scenario. In some examples, the computing system may integrate and order the annotations, which may be treated as textual data, into a specific natural language syntax. One example of a description may include “a vehicle driving in a rural area at dusk and encountering a deer crossing.” In some examples, the one or more descriptions may include a broader concept and/or category that is covered by the scenario and/or characterizes the scenario. For example, the computing system may infer a particular combination of annotations to encompass a broader concept of turning or overtaking/passing. In other examples, the computing system may categorize a particular combination of annotations, such as a level of danger and/or risk (e.g., low danger, medium danger, high danger). The computing system may infer or predict a category such as a level of danger depending on how close a set of annotations and/or a structured format resembles a particular combination of annotations that is already categorized. Alternatively, the computing system may infer one or more concepts related to locomotion from the one or more descriptions and categorize the one or more descriptions accordingly.

In some examples, the generating of the annotations, the conversion of the annotations into a structured format and/or the translation of the annotations and/or the structured format into the one or more descriptions may be based on an ontological framework. For example, the ontological framework may define a criteria of what constitutes high traffic or high traffic density, such as a number of vehicles present within a given area and/or a given frame. Moreover, the ontological framework may define a mapping between annotations and attributes of or inferred by the annotations, which may be indicated within the structured format. For example, annotations of an ego vehicle and a vehicle that is occupying the same lane as the ego vehicle may signify, according to the ontological framework, that the ego vehicle is in front of or behind the vehicle. As another example, an annotation that includes a vehicle driving in a wrong direction (e.g., opposite direction as another vehicle on a same lane) in low visibility, rainy weather, and high traffic density may be correlated to a situation of high danger, according to the ontological framework. As a further example, the ontological framework may map a particular locomotive, navigation, or driving concept or theme (hereinafter “locomotive concept”), such as a left turn or a dangerous driving situation, to one or more particular annotations, one or more combinations of annotations, and/or a particular structured format of annotations. For instance, the ontological framework may associate a particular locomotive concept to a combination of annotations that appears frequently in conjunction with the particular locomotive concept. As one illustrative instance, a locomotive concept of a left turn may appear frequently in conjunction with a combination of annotations such as a left turn signal, an intersection, and a traffic light or other road sign or signal.

The computing system may store relevant processed scenario data, including annotations, the structured format, and/or the one or more descriptions into a database or a datastore (hereinafter “database”). The computing system may map or associate (hereinafter “map”) the annotations, the structured format, and/or the one or more descriptions that correlate to particular scenario data. The computing system may receive a query, and in response to the query, may retrieve a subset (e.g., a portion or an entirety) of the processed scenario data and/or the raw scenario data. In some examples, the computing system may receive a query of a particular locomotive concept or theme, such as a left turn or a dangerous driving situation. The computing system may determine annotations and/or a combination of annotations that are mapped to that particular locomotive concept, and retrieve the processed scenario data and/or the raw scenario data that includes all of, or at least a portion of, those annotations or combination of annotations. Additionally or alternatively, in response to receiving a query that includes a portion of any of the processed scenario data, such as an annotation and/or a description, the computing system may retrieve an associated scenario, including the scenario data and the processed scenario data.

The scenario data may include one or more files or frames, such as a text document and/or one or more media frames (e.g., video frames). In some examples, the computing system may automatically capture scenario data and automatically generate processed scenario data, for example, during a session (e.g., a test driving session). The scenario data may indicate or suggest particular quantitative and/or qualitative attributes such as speed, acceleration, following distance, yielding behavior, braking force, direction of travel, and interaction measurements such as post-encroachment time, time-to-collision, and/or safe time headway. The annotations may include qualitative entities and attributes, and may be obtained, derived, and/or inferred from the scenario data. For example, the annotations may include or be indicative of attributes of dynamic entities and/or of static entities.

Dynamic entities may include an ego vehicle which is responding to an environment, other vehicles of different types such as authority vehicles (e.g., police vehicles and other emergency response vehicles), bicycles, motorcycles, and aerial vehicles such as helicopters for emergency deployment, pedestrians, and/or animals. Attributes of dynamic entities may include or identify types of the entities, initial status of the entities such as facing direction, activities of the entities, such as traveling direction along longitudinal, lateral, and/or elevational perspectives, and other activities of the entities such as signaling including lane change signaling, turn signaling, and/or emergency signaling, and/or other visual or audio signaling such as honking. In some examples, the initial status (e.g., the facing direction) and the activities (e.g., traveling direction) may encompass spatial relationships between entities such as relative orientations and/or relative directions, depicted in a media frame. For example, the orientations and/or relative directions may be relative to an ego vehicle. In some examples, the attributes of dynamic entities may include an intent which may be inferred based on type of that dynamic entity, signaling, trajectory, and/or inferred or predicted trajectory of that dynamic entity, and/or a historical or inferred behavior of that dynamic entity or of that type of dynamic entity. For example, a specific vehicle or a vehicle falling under a specific vehicle type, category, or classification may historically have been associated with, or otherwise may be inferred to have, aggressive or egoistic behavior such as frequently attempting to overtake other vehicles. In such a situation, the intent of that specific vehicle may be more likely to be inferred as an aggressive intent rather than an innocent or mistaken intent. An example of an inferred aggressive intent may include overtaking or passing other vehicles. To the contrary, if a specific vehicle has historically been associated with non-aggressive or altruistic behavior such as typically refraining from overtaking other vehicles, then the intent of that specific vehicle may be more likely to be inferred as an innocent or mistaken intent, such as driving on an improper lane or in an opposite direction lane. In some examples, inferred intent may be included in the one or more descriptions rather than in the annotations or the structured format.

Meanwhile, static entities and attributes thereof may include or indicate specific road demarcations such as lanes and/or barriers, road types (e.g., road surface material and/or properties), road layouts, traffic signs, traffic lights, relative directions of travel of the lanes, traffic densities and/or distributions, and visibility or degree of lighting which may be obtained or based on any shadows or angles of sunlight, and/or any weather conditions.

In some examples, the computing system may further generate and/or predict additional scenarios from any of the stored scenarios, and/or predict one or more subsequent scenarios or outcomes from the scenarios. For example, the computing system may generate a new scenario having a new combination of annotations “urban,” “night,” “snow,” and “emergency vehicle,” in order to conduct testing on a scenario of encountering an emergency vehicle in a snowy nighttime environment in an urban setting. As another example, the computing system may generate a new scenario that is complementary to an existing stored scenario. For example, if an existing scenario corresponds to a concept of passing from a right side, then the computing system may generate a new scenario of passing from a left side. Generating new scenarios is further described in U.S. patent application Ser. No. 18/365,205, filed Aug. 3, 2023, which is hereby incorporated by reference in its entirety. Simulations of the new scenario may elucidate and adjust for conditions such as reduced visibility due to a slightly larger distance from a driver side of a passing vehicle to a right side of the passing vehicle, compared to a distance from the driver side to a left side of the passing vehicle.

By predicting one or more subsequent scenarios and/or outcomes, the computing system may predict an impending dangerous situation that may result in a future disengagement and/or unscheduled or unplanned interruption. By predicting an impending dangerous situation, the computing system may provide a warning that some other action should be undertaken to prevent the dangerous situation. A disengagement may encompass a situation in which a semi-autonomous or autonomous vehicle is returned to manual control from autonomous control. For example, the computing system may predict that a tailgating vehicle behind an ego vehicle in limited visibility and/or inclement weather conditions is a dangerous situation that may lead to an accident or disengagement, unless the ego vehicle pulls over.

Subsequent figures further elucidate some of the aforementioned details and illustrate how the processing of raw scenario data, including generating or creating annotations, generating a structured format of the annotations, and/or characterizing a scenario, depends on attributes such as a historical or inferred behavior of a particular vehicle or vehicle type of a non-ego vehicle (e.g., a surrounding vehicle besides the ego vehicle that affects locomotion decisions of the ego vehicle), a vehicle type (e.g., an authority vehicle or an aerial vehicle) of the non-ego vehicle, a specific road geometry or arrangement. The exemplary figures demonstrate the diversity of scenario classifications which are stored, categorized, and retrievable.

FIG. 1A illustrates an example implementation or scenario (hereinafter “implementation”) of a computing system 102, which may be associated with an ego vehicle, that automatically obtains or derives raw scenario data, processes the raw scenario data to generate and characterize scenarios, stores the scenarios within a database (e.g., a searchable and/or indexed database, such as a database 130), and performs other predictive or inferring functions regarding the scenarios. In some examples, the raw scenario data may be continuously obtained, and include or be derived from sensor data from sensors of one or more modalities (e.g., Lidars, radars, cameras, GPS, sonar, ultrasonic, IMU (inertial measurement unit), accelerometers, gyroscopes, magnetometers, and FIR (far infrared) sensors), media data, and/or textual data. The raw scenario data may include structured and/or unstructured data and be manifested in any format, including text and/or media. The raw scenario data may be ingested, originate from, and/or be combined, merged, or fused (hereinafter “combined”) from different data sources and/or formats. Combining from different data sources and/or formats may encompass normalizing the different formats into a standardized format. The processing of the raw scenario data may encompass generating annotations, generating a structured format of the annotations, and generating one or more descriptions to characterize the scenarios.

The implementation can include at least one computing device 104 which may be operated by an entity such as a user, and may include or be part of a human machine interface (HMI). The user may submit a request or query through the computing device 104. The computing device 104 may receive the request or query from the user or from another computing device, computing process, artificial intelligence (AI) process, or pipeline. Such a request or query may relate or pertain to operations to retrieve, search for, or mine (hereinafter “retrieve”) one or more scenarios. A portion or all of the results including the scenarios and associated metadata, such as the raw scenario data and/or the processed scenario data, may be stored in the database 130, as will be subsequently described. In general, the user can interact with the database 130 directly or over a network 106, for example, through one or more graphical user interfaces, application programming interfaces (APIs), and/or webhooks running on the computing device 104. The computing device 104 may include one or more processors and memory. In some examples, the computing device 104 may visually render any outputs generated, such as the scenarios.

The computing system 102 may include one or more processors 103 which may be configured to perform various operations by interpreting machine-readable instructions, for example, from a machine-readable storage media 112. In some examples, the one or more processors 103 may be combined or integrated into a single processor, and some or all functions performed by one or more of the processors 103 may not be spatially separated, but instead may be performed by a common processor. The one or more processors 103 may be physical or virtual entities. For example, as physical entities, the one or more processors 103 may include one or more processing circuits, each of which can include one or more processing cores. Additionally or alternatively, for example, as virtual entities, the one or more processors 103 may be encompassed within, or manifested as, a program within a cloud environment. The one or more processors 103 may constitute separate programs or applications compared to machine learning components (e.g., one or more machine learning components 111). The computing system 102 may also include a storage 114, which may include a cache for faster access compared to the database 130.

The one or more processors 103 may further be connected to, include, or be embedded with a logic 113 which, for example, may include, store, and/or encapsulate instructions that are executed to carry out the functions of the one or more processors 103. In general, the logic 113 may be implemented, in whole or in part, as software that is capable of running on the computing system 102, and may be read or executed from the machine-readable storage media 112. The logic 113 may include, as nonlimiting examples, parameters, expressions, functions, arguments, evaluations, conditions, and/or code. Here, in some examples, the logic 113 encompasses functions of or related to obtaining or deriving, processing and/or analysis of raw scenario data to generate and characterize a scenario, and storing the processed raw scenario data and/or the raw scenario data within the database 130. Functions or operations described with respect to the logic 113 may be associated with a single processor or multiple processors.

The database 130 may include, or be capable of obtaining, the raw scenario data and/or the processed scenario data corresponding to different scenarios. The database 130 may store any intermediate and/or final outputs during the processing of the raw scenario data. The database 130 may store each different scenario such that the raw scenario data and the processed scenario data corresponding to a particular scenario is mapped together or linked (hereinafter “mapped”). In some examples, the raw scenario data may refer to data of a driving scenario that has not been augmented with annotations, tags, and/or labels (hereinafter “annotations”). Meanwhile, the processed scenario data may be augmented with annotations which describe one or more characteristics of an environment of a driving scenario in accordance with an ontological framework. These characteristics may include objects, entities, events, activities, and/or inferences. As a particular example, annotations may correspond to bounding boxes that delineate boundaries of entities. As another example, the annotations may correspond to inferences regarding relative positions of an entity and/or inferred intentions or activities of an entity. The database 130 may also store one or more results such as one or more future predicted scenarios, and evaluations regarding the scenarios, for example, indicative of a level of danger and/or a probability or confidence level regarding the level of danger.

The database 130 may also store any intermediate or final outputs from training of machine learning components 111, results outputted as a result of execution by the machine learning components 111, and/or attributes, such as feature weights, corresponding to operations of the machine learning components 111.

The computing system 102 may also include, be associated with, and/or be implemented in conjunction with, the machine learning components 111, which may encompass an LLM. The machine learning components 111 may perform unsupervised learning. In some examples, the machine learning components 111 may perform and/or execute functions in conjunction with the logic 113. Thus, any operations or any reference to the machine learning components 111 may be understood to potentially be implemented in conjunction with the logic 113 and/or the computing system 102. The machine learning components 111 may be trained to perform and/or execute certain functions, such as categorizing and/or characterizing scenarios, and/or predicting future scenarios or alternative scenarios. In some examples, the generating of annotations and/or the generating of the structured format of the annotations may be performed without the machine learning components 111.

The machine learning components 111, in some examples, may decipher, translate, elucidate, or interpret information from the raw scenario data, from the annotations, and/or from the structured format of the annotations, in order to extract or obtain relevant information to infer or determine a locomotive concept, and predict one or more future or subsequent scenarios and/or alternative scenarios, according to an ontological framework or template (hereinafter “framework”). This ontological framework may include a criteria or guideline of links or associations, or inferred links, between locomotive concepts and annotations or combinations of annotations, and locomotive concepts that are linked to the annotations and/or combination of annotations. For instance, the ontological framework may link a scenario that has annotations including a vehicle and an opposite direction vehicle (e.g., a vehicle driving in an opposite direction) driving in a same lane as the vehicle to a concept of wrong direction driving and/or an attempted overtaking. In particular, the ontological framework may link any combination of annotations indicative of dynamic entities including a vehicle and/or a pedestrian, vehicle and/or pedestrian signaling, and static entities such as a building, a road, and/or a traffic sign, to particular locomotive concepts.

In some examples, the ontological framework may, based on a characterization of a specific locomotive concept, further associate feasible, plausible, or likely subsequent scenarios and/or alternative scenarios. For example, the ontological framework may associate a characterization of a locomotive concept, such as “wrong direction driving,” with a predicted future scenario of an ego vehicle pulling over in order to yield to the vehicle that is traveling in a wrong direction. As another example, the ontological framework may associate a characterization of a locomotive concept of “turning at an uncontrolled intersection” under high density traffic conditions with a predicted future scenario of yielding after the turn has been completed. In some examples, the ontological framework may, from a characterization of a locomotive concept, associate one or more preceding scenarios by predicting one or more previous scenarios that were likely to have occurred previously. For example, the ontological framework may associate a locomotive concept of yielding to a pedestrian at a crosswalk with a previous scenario in which the pedestrian entered the crosswalk prior to a vehicle entering an intersection. Additionally, the ontological framework may associate a given locomotive concept with related (e.g., concepts that are related and have different levels of granularity, such as more general or more specific concepts) and/or alternative permutations of that locomotive concept. For example, if the locomotive concept is or includes jaywalking, then the ontological framework may associate that locomotive concept with pedestrian crossing.

In some examples, the ontological framework may associate or map any combination and/or structured format of annotations to a danger level, such as a probability of disengagement, in order to identify certain combinations of annotations that correspond to a high probability of disengagements (e.g., above a threshold probability, such as 25 percent, 50 percent, 75 percent or any applicable percentage). Thus, if one combination or structured format of annotations is associated with a high probability of disengagement, then a similar combination may likely be associated with a high probability of disengagement.

In some examples, the ontological framework may associate or map any combination and/or structured format of annotations to a predicted sentiment, such as anger and/or aggressiveness. For example, annotations of an overtaking driver on an incorrect lane in combination with other signaling such as honking may signify an angry and/or aggressive driver.

FIGS. 1A and 1B illustrate how a scenario may be characterized based on signaling, visual cues, predicted trajectory, and/or historical or inferred behaviors of dynamic entities within a driving environment. A scenario such as that illustrated in FIGS. 1A and 1B is useful for simulation because, as an ego vehicle 141 infers an intent of an actor, the ego vehicle 141 may prepare one or more possible maneuvers, for example, to avoid a potential trajectory or path of that actor.

In FIG. 1A, the logic 113 may ingest, obtain, or derive raw scenario data 138. The raw scenario data 138 may be indicative of a driving environment. Although illustrated as pictorial data, the raw scenario data 138 may be manifested in any format, and include any of media data or textual data. The raw scenario data 138 may be obtained by one or more sensors, such as fused sensor data from a camera and a Lidar. The raw scenario data 138 may encompass or correspond to one or more frames, such as one or more image or video frames. Here, in FIG. 1A, the raw scenario data 138 may include the ego vehicle 141 situated or driving on a lane 145, a first opposite direction vehicle 142 on an opposite lane 146, and a second opposite direction vehicle 143, which is facing a wrong direction, on the lane 145. The second opposite direction vehicle 143 may further include a blinking right signaling light 144 (from a perspective of the second opposite direction vehicle 143). The raw scenario data 138 may further include traffic signs 147 and 148, facing opposite directions, to indicate that the lane 145 and the opposite lane 146 are indeed opposite directions. The traffic sign 148 is shown as being blank because the wording is posted on an opposite side and invisible from a perspective from which the raw scenario data 140 was obtained or captured.

The logic 113 may generate, from the raw scenario data 138, or from a subset (e.g., all or a portion, such as a portion of the frames) thereof, processed scenario data 140 by generating and adding annotations to the raw scenario data 138. Alternatively, the logic 113 may obtain the processed scenario data 140 directly, for example, from another source within the computing system 102 or external to the computing system 102. The annotations may include or indicate dynamic entities and attributes thereof, static entities and attributes thereof, and/or environmental conditions. For example, the annotations may include an annotation 161 indicating the ego vehicle 141, an annotation 165 indicating the lane 145, an annotation 162 indicating the first opposite direction vehicle 142, an annotation 166 indicating the opposite lane 146, an annotation 163 indicating the second opposite direction vehicle 143, an annotation 164 indicating a right lane change signaling of the blinking right signaling light 144, and annotations 167 and 168 indicating the traffic signs 147 and 148. Annotations 150, 151, and 152 may further indicate environmental conditions including an indication of dry weather, normal visibility, and normal traffic density or distribution. In some examples, the logic 113 may infer or determine traffic density or distribution based on a number of vehicles within a given area. The logic 113 may also infer or determine visibility and/or weather conditions based on sensor data. The logic 113 may generate the annotations based on recognition of entities, spatial relationships and/or orientations among the entities depicted in the raw scenario data 138. In particular, the logic 113 may determine, infer, or confirm that the lane 145 and the opposite lane 146 are opposite of each other from opposite orientations of the traffic signs 147 and 148. Moreover, the logic 113 may determine or confirm that the ego vehicle 141 and the second opposite direction vehicle 143 are traveling in opposite directions based on relative orientations of the ego vehicle 141 and the second opposite direction vehicle 143. Similarly, the logic 113 may determine or confirm that the ego vehicle 141 and the first opposite direction vehicle 142 are traveling in opposite directions based on relative orientations of the ego vehicle 141 and the first opposite direction vehicle 142.

Next, in FIG. 1B, from the processed scenario data 140, the logic 113 may generate one or more structured formats of the annotations by converting the annotations. The structured formats may be hierarchical, and include statuses or states and activities of the ego vehicle 141, the opposite direction vehicle 142, and the opposite direction vehicle 143, which correspond to structured formats 170, 180, and 190, respectively. The activities may include longitudinal activities which relate to locomotion along a direction of, or parallel to, the orientation of the lane 145 being travelled on by the ego vehicle 141. The activities may further include lateral activities which relate to locomotion in a perpendicular or orthogonal direction to the orientation of the lane 145. In some examples, for aerial vehicles, the activities may further include elevational activities that relate to locomotion perpendicular to a surface of the lane that the ego vehicle 141 is traveling on.

The logic 113 may, in conjunction with the machine learning components 111, infer and generate one or more descriptions or characterizations (hereinafter “descriptions”) of or related to locomotive concepts or other concepts (e.g., sentiment) encapsulated within the processed scenario data 140 and/or the structured formats 170, 180, and 190. The logic 113 may generate the descriptions based on actual events occurring and/or inferred intents of dynamic entities, as evidenced by signaling, visual cues, predicted trajectories, and/or historical or inferred behaviors. In some examples, the logic 113 may generate different or alternative descriptions depending on different inferences of intent, especially if one or more of the inferences is sufficiently uncertain (e.g., below a confidence level or a probability). For example, in FIG. 1B, the intent of the second opposite direction vehicle 143 may be ambiguous because the second opposite direction vehicle 143 may be signaling to change to the lane 146 without overtaking the first opposite direction vehicle 142, or may be intending to change to the lane 146 only after overtaking the first opposite direction vehicle 142. In such an ambiguous situation, the logic 113 may generate different and/or alternative descriptions 195 and 198. Although the descriptions 195 and 198 are shown for illustrative purposes, the descriptions 195 and 198 are merely exemplary and are meant to illustrate that the logic 113 generates descriptions to capture the locomotive concepts or potential locomotive concepts within the processed scenario data 140 and/or the structured formats 170, 180, and 190. For example, other descriptions may capture sentiments, such as a level of anger or aggressiveness associated with a driver or entity behavior. Thus, the descriptions 195 and 198, and any subsequent descriptions in the subsequent FIGS., are meant to be construed as exemplary and not meant to be construed in a limiting sense.

Here, the description 195 indicates that the second opposite direction vehicle 143 is intending to pass or overtake the first opposite direction vehicle 142 before switching to the lane 146, while the description 198 indicates that the second opposite direction vehicle 143 is intending to switch to the lane 146 without overtaking the first opposite direction vehicle 142. In some examples, historical behaviors of the second opposite direction vehicle 143, or historical behaviors of a same type or category of vehicle as the second opposite direction vehicle 143, may inform an intent of the second opposite direction vehicle 143. For example, if a historical behavior of the second opposite direction vehicle 143 is aggressive, the logic 113 may infer an aggressive or egoistic intent of the second opposite direction vehicle 143 in a higher proportion of scenarios. To the contrary, if a historical behavior of the second opposite direction vehicle 143 is non-aggressive, the logic 113 may infer a non-aggressive or altruistic intent of the second opposite direction vehicle 143.

In some examples, as evidence in FIG. 1B, locomotive concepts and/or other concepts may be captured within the descriptions 195 and/or 198. In some examples, the logic 113 may infer, from the descriptions 195 and 198, and/or from the structured formats 170, 180, and 190, a probability of a dangerous situation such as a disengagement or an accident. Based on the correlation of structured formats to a probability of a dangerous situation, the logic 113 may infer that other scenarios corresponding to similar structured formats may also have a similar probability of a dangerous situation.

Alternatively, the logic 113 may infer, from the descriptions 195 and 198, one or more locomotive concepts or other concepts (e.g., sentiments) related to the descriptions. The logic 113 may utilize these locomotive concepts, which are either evident in the descriptions 195 and/or 198, or inferred from the descriptions 195 and/or 198, and/or expand or generalize these locomotive concepts to other related concepts, in order to categorize or classify (hereinafter “categorize”) the descriptions 195 and 198 as well as the processed scenario data 140 and/or the raw scenario data 138. By categorizing accordingly, the logic 113 may facilitate efficient retrieval of any of the processed scenario data 140 and/or the raw scenario data 138, and the descriptions 195 and 198.

The logic 113 may store or catalog, as scenario information, the processed scenario data 140, the structured formats 170, 180, and 190, the descriptions 195 and/or 198, and/or the raw scenario data 138, along with associated metadata (e.g., any additional inferences from the scenario information) within the database 130. In such a manner, the logic 113 may link or associate scenario information that was derived or generated from the raw scenario data 138 and/or from the processed scenario data 140. The logic 113 may further store, within the database 130, any simulation results or outputs from running or executing simulations from the scenario information. The scenario information may be searchable or retrievable.

The logic 113 may receive a query that is related to a potential locomotive concept or other concept (e.g., sentiment or emotion) captured by or inferred from the descriptions 195 and/or 198, the processed scenario data 140 or the structured formats 170, 180, and 190. In response, the logic 113 may output any of the scenario information. The logic 113 may decipher the query and infer locomotive concepts and other concepts related to the query based on the ontological framework, which links potentially related locomotive concepts and/or terms. The linked terms may include any terms of or related to the locomotive concepts or other concepts captured within the scenario information, actions of the first opposite direction vehicle 142 and/or the second opposite direction vehicle 143, possible responses by the ego vehicle 141 and/or by the first opposite direction vehicle 142, and/or possible intents or intended behaviors of the second opposite direction vehicle 143 and/or of the first opposite direction vehicle 142. For example, “overtaking,” “passing,” “wrong direction driving,” “yielding,” “aggressive driving,” and/or “reckless driving,” may be terms that are linked to the scenario information.

The logic 113 may, from the scenario information or a portion thereof, predict one or more subsequent scenarios, such as one or more highest probability subsequent scenarios. For example, the logic 113 may predict that a subsequent scenario includes the second opposite direction vehicle 143 overtaking the first opposite direction vehicle 142, and the second opposite direction vehicle 143 merging into the opposite lane 146. Alternatively, the logic 113 may predict a response by the ego vehicle 141 of pulling over to yield to the second opposite direction vehicle 143.

Additionally, the logic 113 may generate one or more additional scenarios from the scenario information as presented in FIGS. 1A and 1B. For example, the logic 113 may modify any of the environmental conditions, such as the weather, visibility, and/or a traffic density or distribution, as indicated by the annotations 150, 151, and 152. Rainier or snowier weather, lower visibility, and/or a higher traffic density may signify more dangerous conditions and a lower reaction time for the ego vehicle 141. Thus, upon recognizing such situations, the ego vehicle 141 may increase its level of awareness, for example, by activating additional sensors or increasing a level of power of an existing sensor. In some examples, the logic 113 may generate additional scenarios by switching or changing positions of non-ego vehicles (e.g., the first opposite direction vehicle 142 and the second opposite direction vehicle 143), and/or between the ego vehicle 141 and the non-ego vehicles. For instance, a specific alternative scenario may include positioning the first opposite direction vehicle 142 in front of the ego vehicle 141 and the second opposite direction vehicle 143 to a left of the ego vehicle 142.

When an intent of one or more entities is ambiguous, such as illustrated in FIGS. 1A and 1B, the logic 113 may elucidate, elaborate, or clarify an intent using supplemental information such as an additional frame of data and/or an additional dataset. For example, as illustrated in FIGS. 2A and 2B, the logic 113 may obtain or derive both the raw scenario data 138 and raw scenario data 238. FIGS. 2A and 2B thus illustrate a scenario with clearer intent. The raw scenario data 238 may be supplemental to and/or correspond to one or more different frames, such as a subsequent frame, compared to the raw scenario data 138. The raw scenario data 238 may have same or similar entities and characteristics compared to the raw scenario data 138, except that a longitudinal distance between a first opposite direction vehicle 242 and a second opposite direction vehicle 243 has decreased, compared to a longitudinal distance between the first opposite direction vehicle 142 and the second opposite direction vehicle 143 in FIG. 1A. This may suggest or indicate that the second opposite direction vehicle 243 intends to overtake the first opposite direction vehicle 242.

A scenario such as that illustrated in FIGS. 2A and 2B is useful for simulation because, as an ego vehicle 241 clarifies an intent of an actor, the ego vehicle 241 may more clearly formulate a response strategy. For example, if the ego vehicle 241 identifies that another vehicle is intending to overtake a different vehicle, the ego vehicle 241 may implement measures to avoid that vehicle.

In FIG. 2A, the raw scenario data 238 may include the ego vehicle 241 on a lane 245, the first opposite direction vehicle 242 on an opposite lane 246, and the second opposite direction vehicle 243, which is facing a wrong direction, on a lane 245. The second opposite direction vehicle 243 may further include a blinking right signaling light 244. The raw scenario data 238 may further include traffic signs 247 and 248, facing opposite directions, to indicate that the lane 245 and the opposite lane 246 are indeed opposite directions. The ego vehicle 241 may be implemented as the ego vehicle 141 of FIGS. 1A and 1B, the lane 245 may be implemented as the lane 145, the opposite lane 246 may be implemented as the opposite lane 146, the blinking right signaling light 244 may be implemented as the blinking right signaling light 144, and the traffic signs 247 and 248 may be implemented as the traffic signs 147 and 148. The first opposite direction vehicle 242 and the second opposite direction 243 vehicle may be implemented as the first opposite direction vehicle 142 and the second opposite direction vehicle 143, respectively, with a difference of a relative spacing between the first opposite direction vehicle 242 and the second opposite direction 243 being less than that between the first opposite direction vehicle 142 and the second opposite direction vehicle 143.

In an analogous manner as shown in FIG. 1A, the logic 113 may generate, from the raw scenario data 238 or from a subset (e.g., a portion, or all) thereof, processed scenario data 240 by generating and adding annotations to the raw scenario data 238. In some examples, the logic 113 may directly obtain the processed scenario data 240. The annotations may include an annotation 261 indicating the ego vehicle 241, an annotation 265 indicating the lane 245, an annotation 262 indicating the first opposite direction vehicle 242, an annotation 266 indicating the opposite lane 246, an annotation 263 indicating the second opposite direction vehicle 243, an annotation 264 indicating a left lane change signaling of the blinking left signaling light 244, and annotations 267 and 268 indicating the traffic signs 247 and 248. The annotations 250, 251, and 252 may further indicate environmental conditions including an indication of dry weather, normal visibility, and normal traffic density or distribution.

Next, in FIG. 2B, in an analogous manner as shown in FIG. 1B, from the processed scenario data 240, the logic 113 may generate one or more structured formats 270, 280, and 290 of the annotations by converting the aforementioned annotations 261, 262, 263, 264, 265, 267, 268, and 250-252. The structured formats 270, 280, and 290 may be hierarchical, and include statuses or states and activities of the ego vehicle 241, the first opposite direction vehicle 242, and the second opposite direction vehicle 243, which correspond to the structured formats 270, 280, and 290, respectively. Thus, the structured formats 270, 280, and 290 may be implemented in a same or similar manner as the structured formats 170, 180, and 190. Within the structured format 290, a longitudinal activity of the second opposite direction vehicle 243 is indicated to be overtaking. The intent of overtaking may be inferred due to differences in relative positions of the second opposite direction vehicle 243 and the first opposite direction vehicle 242 between the frames (e.g., between the processed scenario data 240 and the processed scenario data 238). In particular, a distance between the second opposite direction vehicle 243 and the first opposite direction vehicle 242 decreasing without the second opposite direction vehicle 243 changing lanes. The structured format 290 is distinguished from the structured format 190. In the former, the second opposite direction vehicle 243 is indicated to be overtaking but in the latter, the intent of the second opposite direction vehicle 243 is unclear. Meanwhile, within the structured format 280, a longitudinal activity of the first opposite direction vehicle 242 is indicated to be yielding, as distinguished from the structured format 180, which does not indicate any yielding action.

The logic 113 may, in conjunction with the machine learning components 111, infer and generate one or more descriptions or characterizations (hereinafter “descriptions”) of locomotive concepts encapsulated within the processed scenario data 140 and 240 and/or the structured formats 270, 280, and 290, in an analogous manner as shown in FIG. 1B. The logic 113 may generate descriptions 295 and 298 that indicate an inferred intent of overtaking and that the overtaking is from a vehicle driving on an opposite side of traffic or an incorrect lane. Although the descriptions 295 and 298 are shown for illustrative purposes, the logic 113 may generate other descriptions as well, which also capture the locomotive concepts or potential locomotive concepts within the processed scenario data 140, 240 and/or the structured formats 270, 280, and 290.

The logic 113 may store or catalog, as scenario information, the processed scenario data 140 and 240, the structured formats 270, 280, and 290, the descriptions 295 and/or 298, and/or the raw scenario data 238 together as one scenario within the database 130. In such a manner, the logic 113 may link or associate scenario information that was derived or generated from the raw scenario data 238. The logic 113 may further store, within the database 130, any simulation results or outputs from running or executing simulations from the scenario information. The scenario information may be searchable or retrievable. For example, if the logic 113 receives a query that is related to a potential locomotive concept or other concept captured by or inferred from the descriptions 295 and/or 298, the processed scenario data 140, 240 or the structured formats 270, 280, and 290, the logic 113 may output any of the scenario information.

The logic 113 may, from the scenario information or a portion thereof, predict one or more subsequent scenarios. For example, the logic 113 may predict that a subsequent scenario includes the second opposite direction vehicle 243 overtaking the first opposite direction vehicle 242, and the second opposite direction vehicle 243 merging into the opposite lane 246.

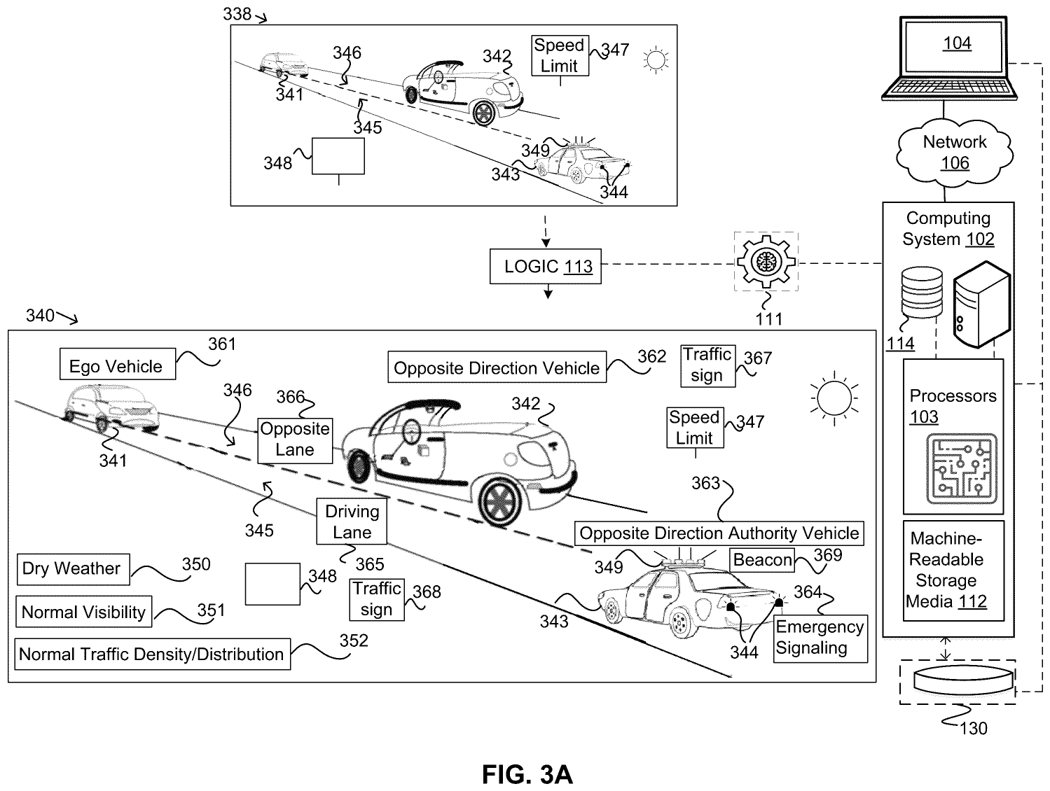

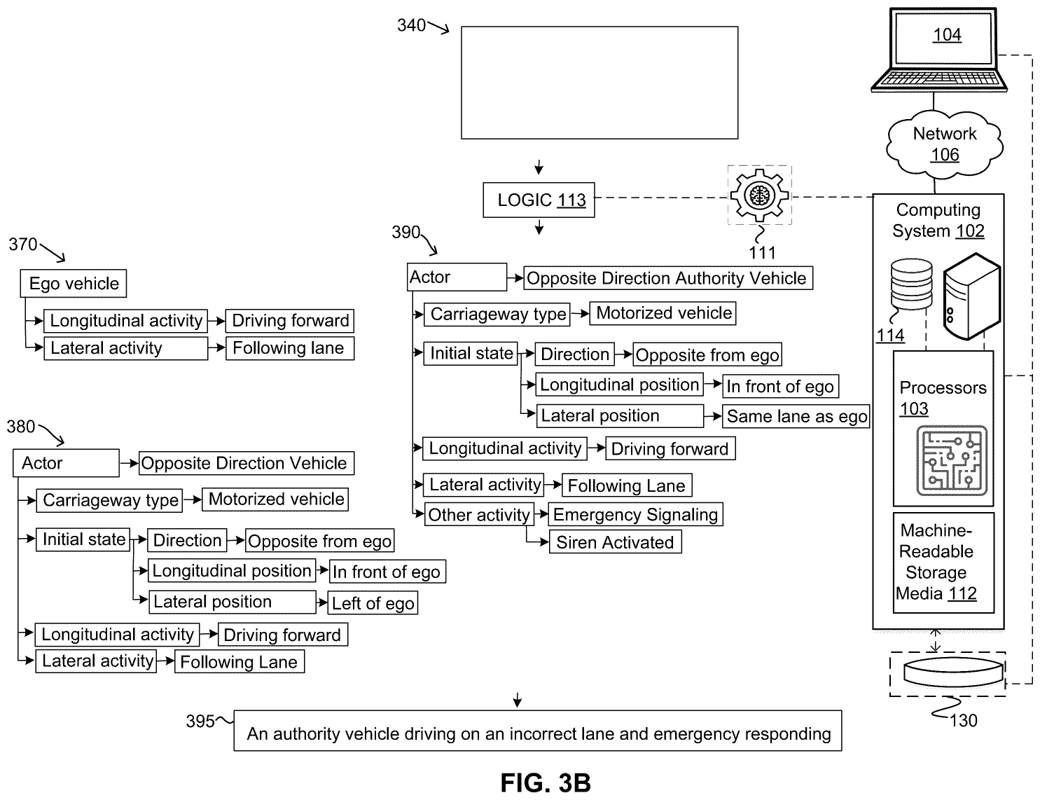

FIGS. 3A and 3B illustrate how a scenario may be characterized based on signaling from dynamic entities and/or based on types, categories, or classifications (hereinafter “types”) of dynamic entities. Such a scenario is useful for simulation because, upon identifying a type of a dynamic entity, an ego vehicle 341 may implement a response accordingly. For example, the ego vehicle 341 may pull over soon after identifying an authority vehicle in an incorrect lane, whereas the ego vehicle 341 may refrain from pulling over or pull over later upon identifying a non-authority vehicle in an incorrect lane. Other types of dynamic entities may include pedestrian conveyances such as human powered devices (e.g., bicycles, tricycles, carriages, roller skates, skateboards, and non-motorized vehicles).

In FIG. 3A, the logic 113 may ingest, obtain, or derive raw scenario data 338. The raw scenario data 338 may be implemented in a similar manner as the raw scenario data 138 and/or 238, although content within the raw scenario data 338 is different and illustrates a different locomotive concept. Here, in FIG. 3A, the raw scenario data 338 may include the ego vehicle 341 on a lane 345, a first opposite direction vehicle 342 on an opposite lane 346, and a second opposite direction vehicle 343, which is facing a wrong direction, on the lane 345. The second opposite direction vehicle 343 may further include a flashing emergency signaling light 344 and a beacon 349. The flashing emergency signaling light 344 and the beacon 349 may indicate an emergency or urgent situation, which may indicate to the ego vehicle 341 to yield. The flashing emergency signaling light 344 and the beacon 349 may also indicate or suggest a type of vehicle, such as an emergency vehicle and/or an authority vehicle. The raw scenario data 338 may further include traffic signs 347 and 348, facing opposite directions, to indicate that the lane 345 and the opposite lane 346 are indeed opposite directions. The ego vehicle 341 may be implemented as the ego vehicle 141 of FIGS. 1A and 1B, the lane 345 may be implemented as the lane 145, the opposite lane 346 may be implemented as the opposite lane 146, and the traffic signs 347 and 348 may be implemented as the traffic signs 147 and 148. The first opposite direction vehicle 342 may be implemented as the first opposite direction vehicle 142.

The logic 113 may generate, from the raw scenario data 338 or from a subset (e.g., all or a portion) thereof, processed scenario data 340 by generating and adding annotations to the raw scenario data 338. Alternatively, the logic 113 may directly obtain the processed scenario data 340. The annotations may include or indicate dynamic entities and attributes thereof, static entities and attributes thereof, and/or environmental conditions. For example, the annotations may include an annotation 361 indicating the ego vehicle 341, an annotation 365 indicating the lane 345, an annotation 362 indicating the first opposite direction vehicle 342, an annotation 366 indicating the opposite lane 346, an annotation 363 indicating the second opposite direction vehicle 343, an annotation 364 indicating the flashing emergency light 344, an annotation 369 indicating the beacon 349, and annotations 367 and 368 indicating the traffic signs 347 and 348. Annotations 350, 351, and 352 may further indicate environmental conditions including an indication of dry weather, normal visibility, and normal traffic density or distribution. In some examples, the logic 113 may infer or determine traffic density or distribution based on a number of vehicles within a given area. The logic 113 may also infer or determine visibility and/or weather conditions based on sensor data. The logic 113 may generate the aforementioned annotations based on recognition of entities, spatial relationships and/or orientations among the entities. In particular, the logic 113 may infer, determine or confirm that the lane 345 and the opposite lane 346 are opposite of each other from opposite orientations of the traffic signs 347 and 348. Moreover, the logic 113 may determine or confirm that the ego vehicle 341 and the second opposite direction vehicle 343 are traveling in opposite directions based on relative orientations of the ego vehicle 341 and the second opposite direction vehicle 343. Similarly, the logic 113 may determine or confirm that the ego vehicle 341 and the first opposite direction vehicle 342 are traveling in opposite directions based on relative orientations of the ego vehicle 341 and the first opposite direction vehicle 342.

Next, in FIG. 3B, from the processed scenario data 340, the logic 113 may generate one or more structured formats of the annotations by converting or reformatting the annotations. The structured formats may be hierarchical, and include statuses or states and activities of the ego vehicle 341, the first opposite direction vehicle 342, and the second opposite direction vehicle 343, which correspond to structured formats 370, 380, and 390, respectively. The activities may include longitudinal activities which relate to locomotion along a direction of, or parallel to, the orientation of the lane 345 being travelled on by the ego vehicle 341. The activities may further include lateral activities which relate to locomotion in a perpendicular or orthogonal direction to the orientation of the lane 345. Here, the structured format 390 may indicate a type of the second opposite direction vehicle 343 as an authority vehicle, which may be inferred or determined by the beacon 349 and the flashing emergency signaling light 344. The structured format 390 may further indicate that the second opposite direction vehicle 343 is emergency signaling and has a siren activated.

The logic 113 may, in conjunction with the machine learning components 111, infer and generate one or more descriptions or characterizations (hereinafter “descriptions”) of locomotive concepts encapsulated within the processed scenario data 340 and/or the structured formats 370, 380, and 390. The logic 113 may generate a description 395 based on inferred intents of dynamic entities, as evidenced by signaling (e.g., emergency signaling and sirens), and/or types of the dynamic entities (e.g., an authority vehicle). The description 395 indicates that an authority vehicle is driving on an incorrect or wrong direction lane and is responding to an emergency.

The logic 113 may store or catalog, as scenario information, the processed scenario data 340, the structured formats 370, 380, and 390, the description 395, and/or the raw scenario data 338 together as one scenario within the database 130. In such a manner, the logic 113 may link or associate scenario information that was derived or generated from the raw scenario data 338 and/or from the processed scenario data 340, which facilitates retrieval of the scenario information. For example, if the logic 113 receives a query that is related to a potential locomotive concept or other concept captured by or inferred from the description 395, the processed scenario data 340 or the structured formats 370, 380, and 390, the logic 113 may output any of the scenario information. Such a query may include a reference to an emergency, a chase, yielding, or urgency.

The logic 113 may, from the scenario information or a portion thereof, predict one or more subsequent scenarios. For example, the logic 113 may predict that a subsequent scenario includes the first opposite direction vehicle 342 and/or the ego vehicle 341 detecting or recognizing an emergency situation and pulling over to a side of a road to yield to the second opposite direction vehicle 343.

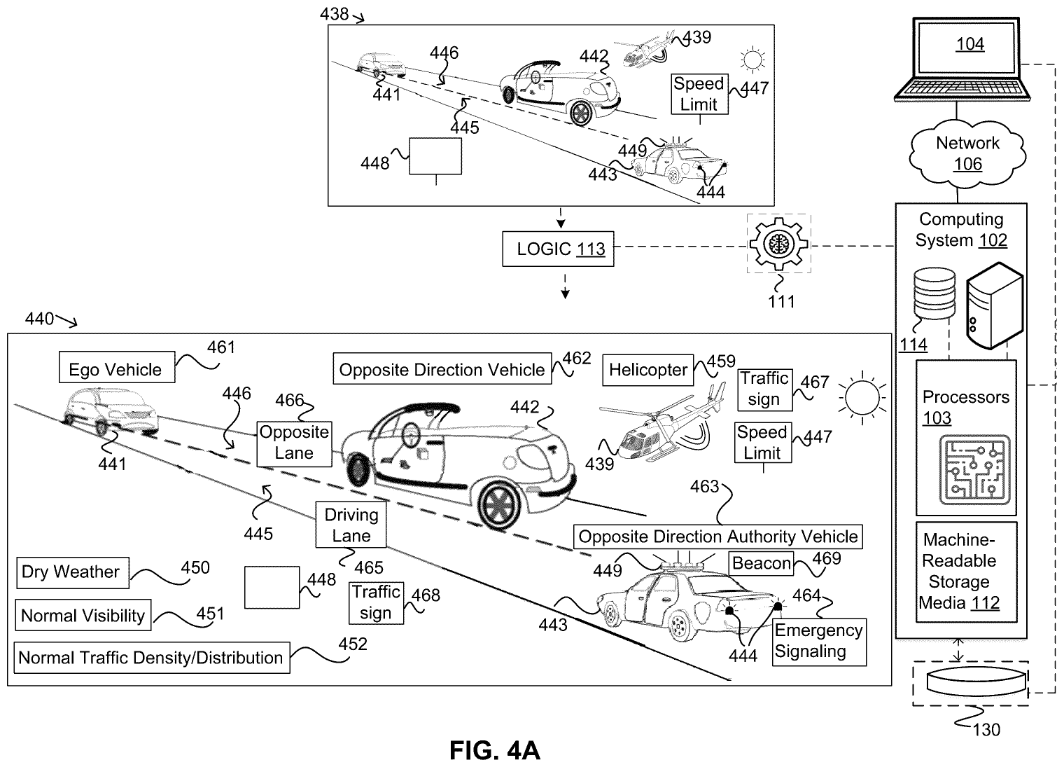

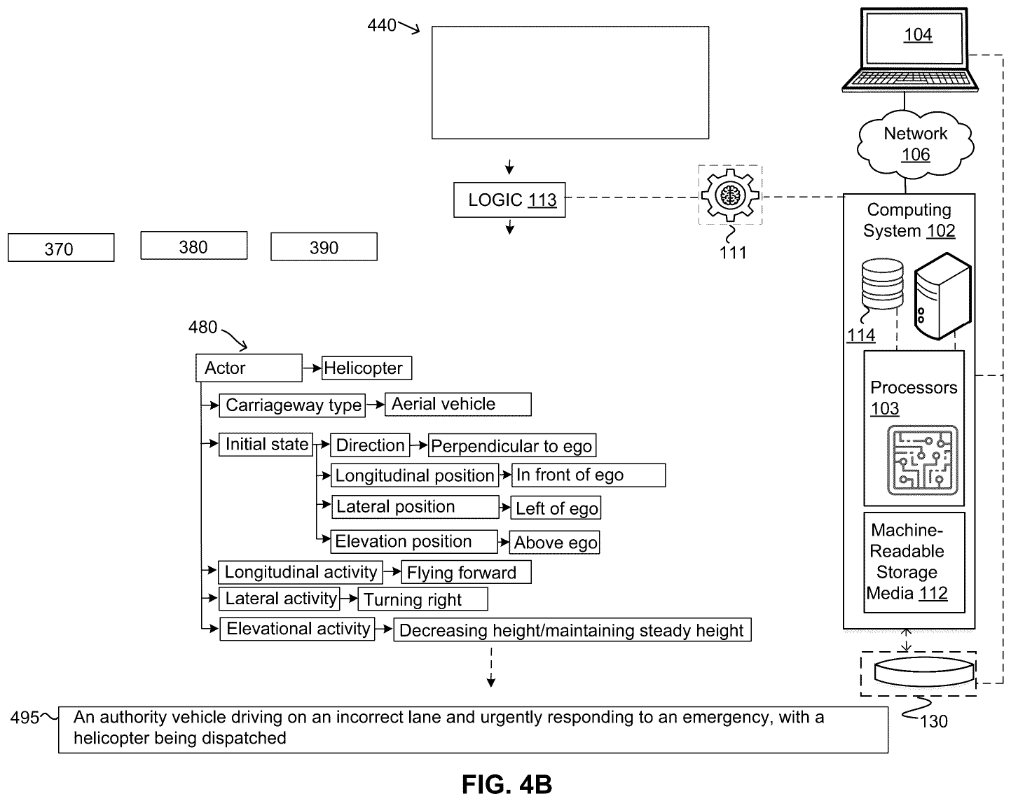

Next, FIGS. 4A and 4B illustrate how a scenario may be characterized based on signaling from dynamic entities and/or based on types, categories, or classifications (hereinafter “types”) of dynamic entities, which may include non-terrestrial (e.g., non-land based) entities. Such a scenario is useful for simulation because a presence and/or activity of different types of dynamic entities, such as an authority vehicle and a helicopter, may provide further context for a situation such as indicating a level of severity or urgency of a situation, such as an emergency. Upon detecting the different types of dynamic entities, an ego vehicle 441 may implement a response in accordance with a level of severity or urgency, such as immediately pulling over.

In FIG. 4A, the logic 113 may ingest, obtain, or derive raw scenario data 438. The raw scenario data 438 may be implemented in a similar manner as the raw scenario data 138, 238 and/or 338. The raw scenario data 438 may include the features and entities of the raw scenario data 338, with an addition of a helicopter 439 or other aerial vehicle equipped to perform surveillance or tracking. Here, the helicopter 439 may further reinforce a concept of an emergency situation, and may increase a perceived urgency of the situation so that all road vehicles, such as the ego vehicle 441, may be programmed to pull over immediately upon recognizing the emergency situation.

In FIG. 4A, the raw scenario data 438 may include the ego vehicle 441 on a lane 445, a first opposite direction vehicle 442 on an opposite lane 446, and a second opposite direction vehicle 443, which is facing a wrong direction, on a lane 445. The second opposite direction vehicle 443 may further include a flashing emergency signaling light 444 and a beacon 449. The raw scenario data 438 may further include traffic signs 447 and 448, facing opposite directions, to indicate that the lane 445 and the opposite lane 446 are indeed opposite directions. The ego vehicle 441 may be implemented as the ego vehicle 341 of FIGS. 3A and 3B, the lane 445 may be implemented as the lane 345, the opposite lane 446 may be implemented as the opposite lane 346, the flashing emergency signaling light 444 may be implemented as the flashing emergency signaling light 344, and the traffic signs 447 and 448 may be implemented as the traffic signs 347 and 348. The first opposite direction vehicle 442 and the second opposite direction 443 vehicle may be implemented as the first opposite direction vehicle 342 and the second opposite direction vehicle 343.

The logic 113 may generate, from the raw scenario data 438 or from a subset (e.g., all or a portion) thereof, processed scenario data 440 by generating and adding annotations to the raw scenario data 438. The processed scenario data 440 may encompass the features of the processed scenario data 340, with an additional annotation 459 corresponding to the helicopter 439.

The annotations may further include an annotation 461 indicating the ego vehicle 441, an annotation 465 indicating the lane 445, an annotation 462 indicating the first opposite direction vehicle 442, an annotation 466 indicating the opposite lane 446, an annotation 463 indicating the second opposite direction vehicle 443, an annotation 464 indicating the flashing emergency signaling light 444, an annotation 469 indicating the beacon 449, and annotations 467 and 468 indicating the traffic signs 447 and 448. Annotations 450, 451, and 452 may further indicate environmental conditions including an indication of dry weather, normal visibility, and normal traffic density or distribution. In some examples, the logic 113 may infer or determine traffic density or distribution based on a number of vehicles within a given area. The logic 113 may also infer or determine visibility and/or weather conditions based on sensor data. The logic 113 may generate the aforementioned annotations based on recognition of entities, spatial relationships and/or orientations among the entities. In particular, the logic 113 may infer, determine or confirm that the lane 445 and the opposite lane 446 are opposite of each other from opposite orientations of the traffic signs 447 and 448. Moreover, the logic 113 may determine or confirm that the ego vehicle 441 and the second opposite direction vehicle 443 are traveling in opposite directions based on relative orientations of the ego vehicle 441 and the second opposite direction vehicle 443. Similarly, the logic 113 may determine or confirm that the ego vehicle 441 and the first opposite direction vehicle 442 are traveling in opposite directions based on relative orientations of the ego vehicle 441 and the first opposite direction vehicle 442.

Next, in FIG. 4B, from the processed scenario data 440, the logic 113 may generate one or more structured formats of the annotations by converting or reformatting the annotations. The structured formats may be hierarchical, and include statuses or states and activities of the ego vehicle 441, the first opposite direction vehicle 442, and the second opposite direction vehicle 443, which correspond to the structured formats 370, 380, and 390, respectively, as previously described in FIG. 3B. The logic 113 may generate an additional structured format 480 corresponding to the helicopter 439. Here, the structured format 480 may indicate a type of the helicopter 439 as an aerial vehicle, which has an elevation position and an elevation activity (e.g., in a direction perpendicular to a plane on which the lane 345 and the opposite lane 346 are situated).

The logic 113 may, in conjunction with the machine learning components 111, infer and generate one or more descriptions or characterizations (hereinafter “descriptions”) of locomotive concepts encapsulated within the processed scenario data 440 and/or the structured formats 370, 380, 390, and 480. The logic 113 may generate a description 495 based on inferred intents of dynamic entities, as evidenced by signaling (e.g., emergency signaling and sirens), and/or types of the dynamic entities (e.g., an authority vehicle, a helicopter). The description 495 indicates that an authority vehicle is driving on an incorrect or wrong direction lane and is responding to an emergency, with an overhead helicopter.

The logic 113 may store or catalog, as scenario information, the processed scenario data 440, the structured formats 370, 380, 390, and 480, the description 495, and/or the raw scenario data 438 together as one scenario within the database 130. In such a manner, the logic 113 may link or associate scenario information that was derived or generated from the raw scenario data 438 and/or from the processed scenario data 440, which facilitates retrieval of the scenario information. For example, if the logic 113 receives a query that is related to a potential locomotive concept or other concept captured by or inferred from the description 495, the processed scenario data 440 or the structured formats 370, 380, 390, or 480, then the logic 113 may output any of the scenario information. Such a query may include, in addition to those pertaining to FIGS. 1A and 1B, reference to surveillance, emergency, a chase, a helicopter, or yielding.

The logic 113 may, from the scenario information or a portion thereof, predict one or more subsequent scenarios. For example, the logic 113 may predict that a subsequent scenario includes the first opposite direction vehicle 442 and/or the ego vehicle 441 detecting or recognizing an urgent emergency situation and immediately pulling over to a side of a road to yield to the second opposite direction vehicle 443, and possibly remaining pulled over until the helicopter 439 is no longer flying overhead.

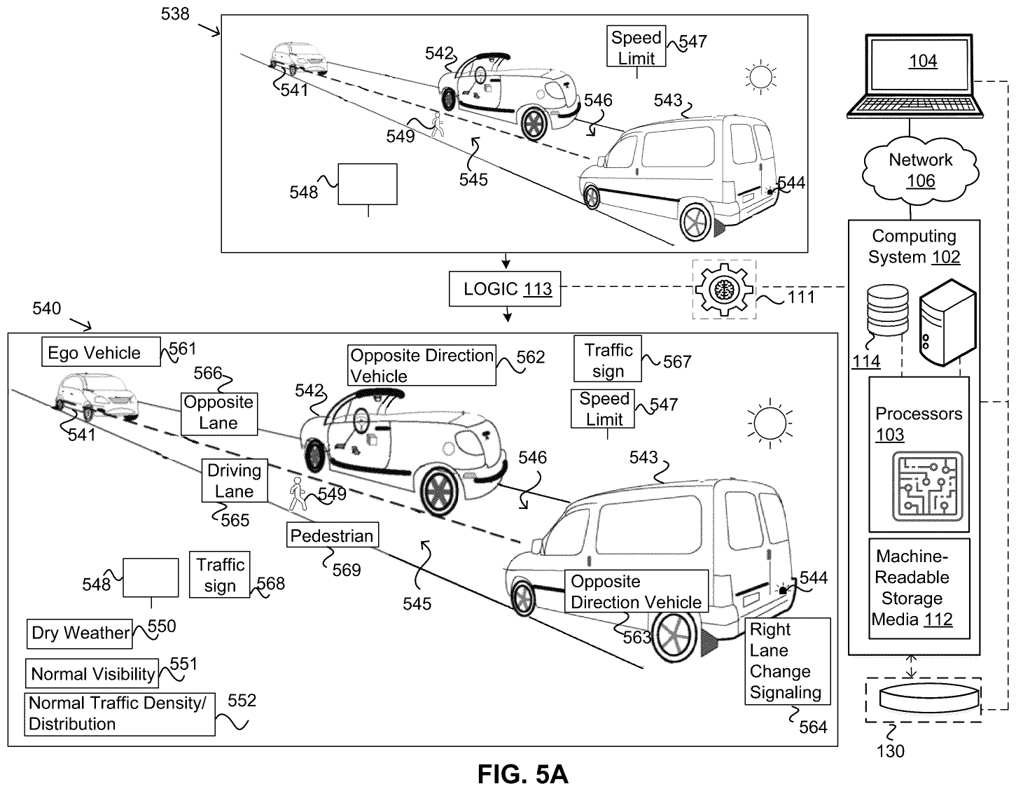

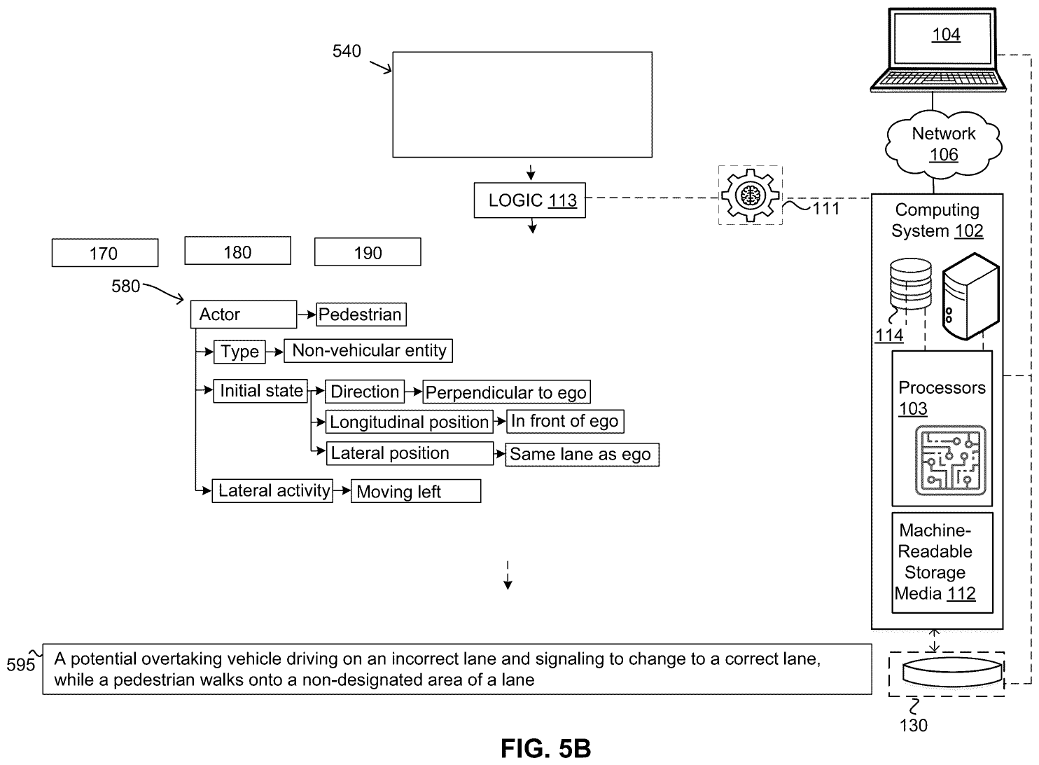

Next, FIGS. 5A and 5B illustrate how a scenario may be characterized based on types of dynamic entities, which may include non-vehicular entities such as pedestrians and/or animals. Such a scenario is useful for simulation in order to identify and properly react to different entities which may have different tendencies, speeds, and characteristics. For example, a pedestrian is typically slower and/or less resistant to impact compared to a vehicle. When an ego vehicle 531 encounters a pedestrian, the ego vehicle 531 may maintain a larger distance from the pedestrian compared to a situation if the ego vehicle encounters a vehicle.

In FIG. 5A, the logic 113 may ingest, obtain, or derive raw scenario data 538. The raw scenario data 538 may be implemented in a similar manner as the raw scenario data 138, 238, 338, and/or 438. The raw scenario data 538 may include the features and entities of the raw scenario data 138, with an addition of a pedestrian 549, and/or some other dynamic non-vehicular entity. Here, the pedestrian 549 may be jaywalking, or otherwise moving on an undefined or undesignated path that is not specifically designated for walking. The ego vehicle 141 may, upon recognition of the pedestrian 549, pull over to a side.

Here, in FIG. 5A, the raw scenario data 538 may include the ego vehicle 541 on a lane 545, a first opposite direction vehicle 542 on an opposite lane 546, and a second opposite direction vehicle 543, which is facing a wrong direction, on the lane 545. The second opposite direction vehicle 543 may further include a blinking right signaling light 544. The raw scenario data 538 may further include traffic signs 547 and 548, facing opposite directions, to indicate that the lane 545 and the opposite lane 546 are indeed opposite directions. The ego vehicle 541 may be implemented as the ego vehicle 141 of FIGS. 1A and 1B, the lane 545 may be implemented as the lane 145, the opposite lane 546 may be implemented as the opposite lane 146, and the traffic signs 547 and 548 may be implemented as the traffic signs 147 and 148. The first opposite direction vehicle 542 may be implemented as the first opposite direction vehicle 142. The second opposite direction vehicle 543 may be implemented as the second opposite direction vehicle 143.

The logic 113 may generate, from the raw scenario data 538 or from a subset (e.g., all or a portion) thereof, processed scenario data 540 by generating and adding annotations to the raw scenario data 538. Alternatively, the logic 113 may directly obtain the processed scenario data 540. The processed scenario data 540 may encompass the features of the processed scenario data 140, with an additional annotation 569 corresponding to the pedestrian 549. The annotations may include an annotation 561 indicating the ego vehicle 541, an annotation 565 indicating the lane 545, an annotation 562 indicating the first opposite direction vehicle 542, an annotation 566 indicating the opposite lane 546, an annotation 563 indicating the second opposite direction vehicle 543, an annotation 564 indicating the blinking right signaling light 544, and annotations 567 and 568 indicating the traffic signs 547 and 548. Annotations 550, 551, and 552 may further indicate environmental conditions including an indication of dry weather, normal visibility, and normal traffic density or distribution. In some examples, the logic 113 may infer or determine traffic density or distribution based on a number of vehicles within a given area. The logic 113 may also infer or determine visibility and/or weather conditions based on sensor data. The logic 113 may generate the aforementioned annotations based on recognition of entities, spatial relationships and/or orientations among the entities. In particular, the logic 113 may infer, determine or confirm that the lane 545 and the opposite lane 546 are opposite of each other from opposite orientations of the traffic signs 547 and 548. Moreover, the logic 113 may determine or confirm that the ego vehicle 541 and the second opposite direction vehicle 543 are traveling in opposite directions based on relative orientations of the ego vehicle 541 and the second opposite direction vehicle 543. Similarly, the logic 113 may determine or confirm that the ego vehicle 541 and the first opposite direction vehicle 542 are traveling in opposite directions based on relative orientations of the ego vehicle 541 and the first opposite direction vehicle 542.

Next, in FIG. 5B, from the processed scenario data 540, the logic 113 may generate one or more structured formats of the annotations by converting or reformatting the annotations. The structured formats may be hierarchical, and include statuses or states and activities of the ego vehicle 541, the first opposite direction vehicle 542, and the second opposite direction vehicle 543, which correspond to the structured formats 170, 180, and 190, respectively. The logic 113 may generate an additional structured format 580 corresponding to the pedestrian 549. Here, the structured format 580 may indicate a type of the pedestrian 549 as a non-vehicular entity.

The logic 113 may, in conjunction with the machine learning components 111, infer and generate one or more descriptions or characterizations (hereinafter “descriptions”) of locomotive concepts encapsulated within the processed scenario data 540 and/or the structured formats 170, 180, 190, and 580. The logic 113 may generate a description 595 based on inferred intents of dynamic entities, as evidenced by signaling, and/or types of the dynamic entities, such as the pedestrian 549. The description 595 indicates that a vehicle is driving on an incorrect or wrong direction lane while a pedestrian is also crossing onto a lane that is non-designated for walking.

The logic 113 may store or catalog, as scenario information, the processed scenario data 540, the structured formats 170, 180, 190, and 580, the description 595, and/or the raw scenario data 538 together as one scenario within the database 130. In such a manner, the logic 113 may link or associate scenario information that was derived or generated from the raw scenario data 538, which facilitates retrieval of the scenario information. For example, if the logic 113 receives a query that is related to a potential locomotive concept or other concept captured by or inferred from the description 595, the processed scenario data 540 or the structured formats 170, 180, 190, or 580, the logic 113 may output any of the scenario information. Such a query may include, in addition to those pertaining to FIGS. 1A and 1B, jaywalking, crossing (e.g., pedestrian crossing), or avoiding a collision.

The logic 113 may, from the scenario information or a portion thereof, predict one or more subsequent scenarios. For example, the logic 113 may predict that a subsequent scenario includes the first opposite direction vehicle 542 and/or the ego vehicle 541 detecting or recognizing the pedestrian 549 and immediately pulling over to a side of a road to yield to the pedestrian 549 and/or moving to avoid the pedestrian 549.

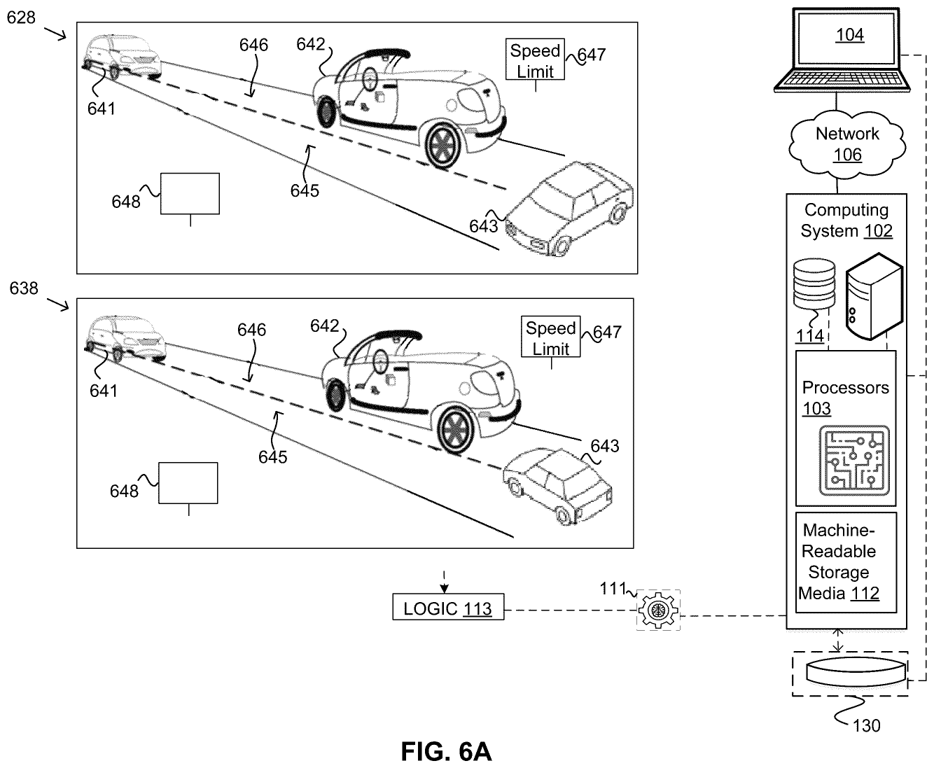

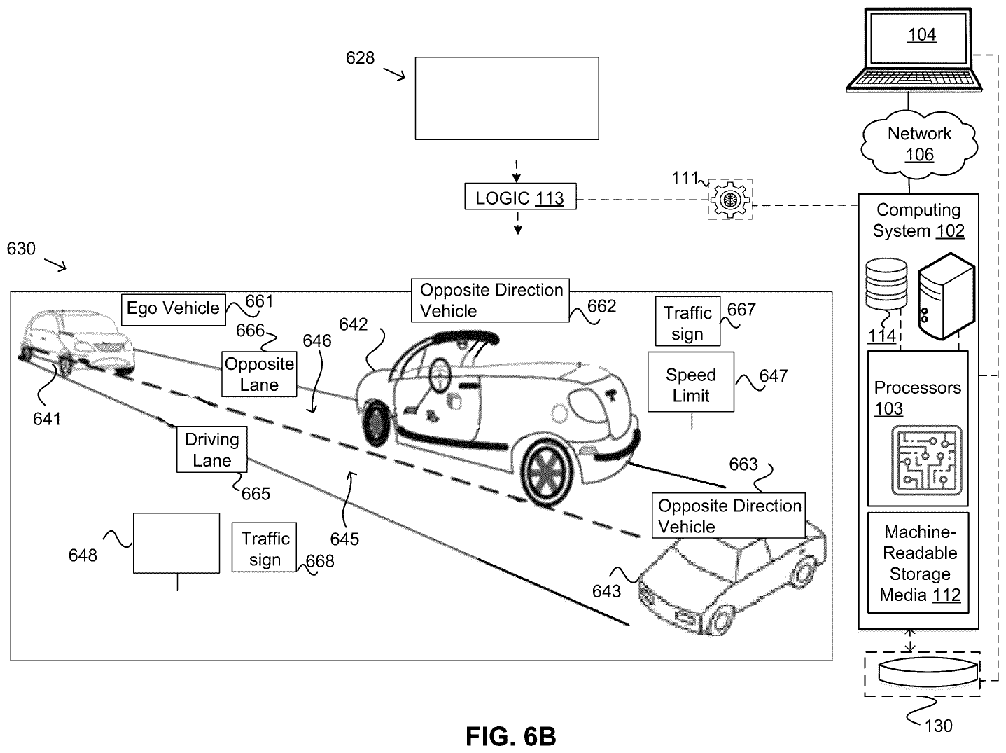

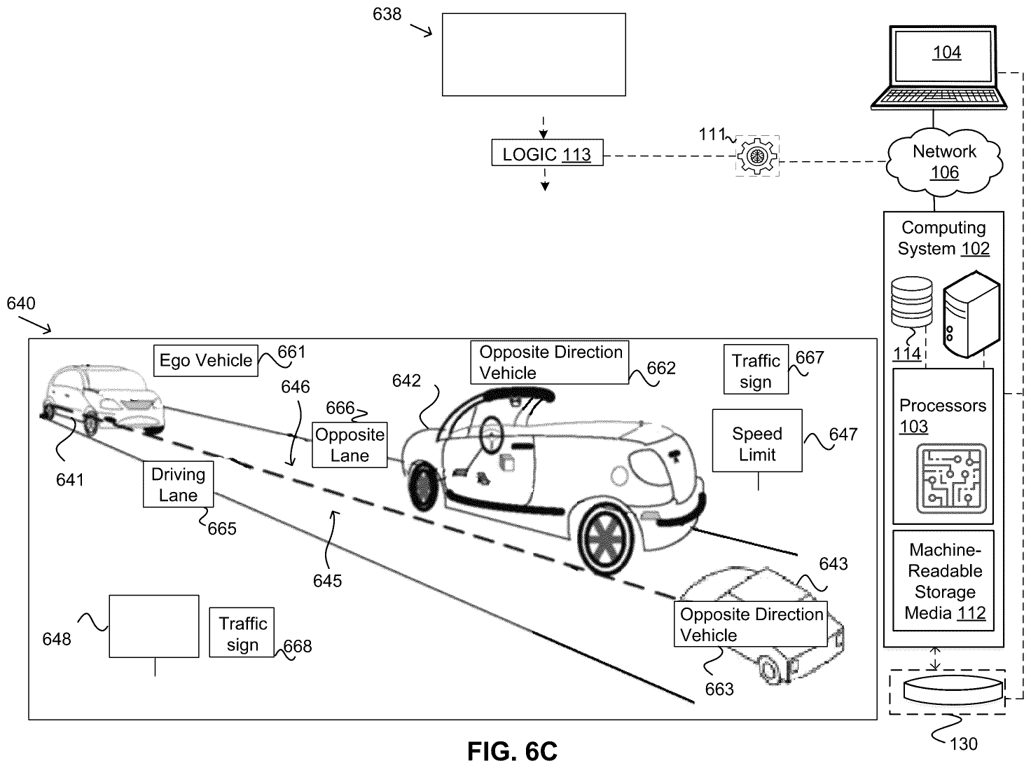

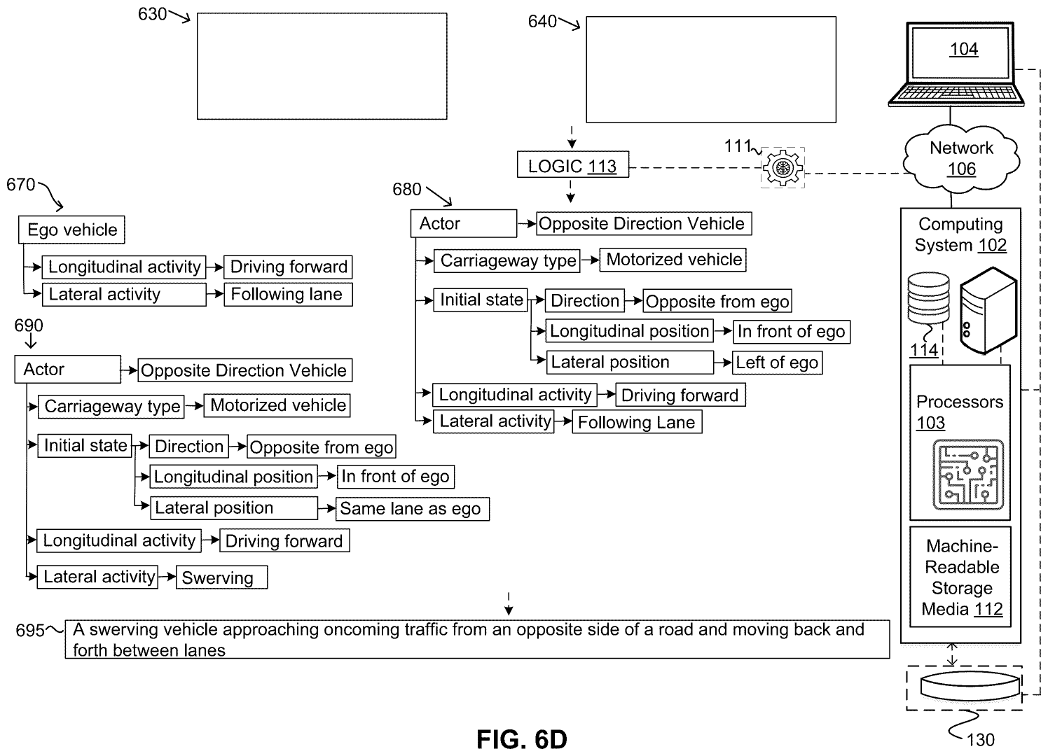

FIGS. 6A-6D illustrate how a scenario may be characterized based on dynamic entity behaviors, including abnormal and/or unpredictable behaviors such as swerving. Such behaviors may apply to vehicular entities and non-vehicular entities. Such a scenario is useful for simulation in order to identify, avoid, and/or mitigate potential dangers which may arise from these behaviors. For example, an ego vehicle 641 may maintain distance from a swerving entity, such as a vehicle or a pedestrian. Other behaviors may include tailgating or forming a roadblock (e.g., two vehicles such as trucks driving side by side over a prolonged period of time).

In FIG. 6A, the logic 113 may ingest, obtain, or derive raw scenario data 628 and/or 638. The raw scenario data 628 and/or 638 may encompass multiple frames and/or datasets, and may be implemented in a similar manner as the raw scenario data 138, 238, 338, 438, and/or 538, although content within the raw scenario data 628 and/or 638 is different and illustrates a different locomotive concept. Here, in FIG. 6A, the raw scenario data 628 may include the ego vehicle 641 on a lane 645, a first opposite direction vehicle 642 on an opposite lane 646, and a second opposite direction vehicle 643, which is facing a wrong direction, on the lane 645. The second opposite direction vehicle 643 may be oriented non-parallel with respect to the first opposite direction vehicle 642 and/or the ego vehicle 641. The raw scenario data 628 may further include traffic signs 647 and 648, facing opposite directions, to indicate that the lane 645 and the opposite lane 646 are indeed opposite directions. The ego vehicle 641 may be implemented as the ego vehicle 141 of FIGS. 1A and 1B, the lane 645 may be implemented as the lane 145, the opposite lane 646 may be implemented as the opposite lane 146, and the traffic signs 647 and 648 may be implemented as the traffic signs 147 and 148. The first opposite direction vehicle 642 may be implemented as the first opposite direction vehicle 142.

Meanwhile, the raw scenario data 638 may include the same entities as in the raw scenario data 628, but an absolute and/or relative orientation and/or a position of the second opposite direction vehicle 643 may have changed from that in the raw scenario data 638. The positioning of the second opposite direction vehicle 643 being non-parallel with either the lane 645 or the opposite lane 646, and the change in the relative orientation of the second opposite direction vehicle 643, may indicate or suggest a swerving behavior.

As illustrated in FIG. 6B, the logic 113 may generate, from the raw scenario data 628, or from a subset (e.g., all or a portion) thereof, processed scenario data 630 by generating and adding annotations to the raw scenario data 628. Alternatively, the logic 113 may directly obtain the processed scenario data 630. The annotations may include or indicate dynamic entities and attributes thereof, static entities and attributes thereof, and/or environmental conditions. For example, the annotations may include an annotation 661 indicating the ego vehicle 641, an annotation 665 indicating the lane 645, an annotation 662 indicating the first opposite direction vehicle 642, an annotation 666 indicating the opposite lane 646, an annotation 663 indicating the second opposite direction vehicle 643, and annotations 667 and 668 indicating the traffic signs 647 and 648. Annotations 650, 651, and 652 may further indicate environmental conditions including an indication of dry weather, normal visibility, and normal traffic density or distribution. In some examples, the logic 113 may infer or determine traffic density or distribution based on a number of vehicles within a given area. The logic 113 may also infer or determine visibility and/or weather conditions based on sensor data. The logic 113 may generate the aforementioned annotations based on recognition of entities, spatial relationships and/or orientations among the entities. In particular, the logic 113 may infer, determine or confirm that the lane 645 and the opposite lane 646 are opposite of each other from opposite orientations of the traffic signs 647 and 648. Moreover, the logic 113 may determine or confirm that the ego vehicle 641 and the second opposite direction vehicle 643 are traveling in opposite directions based on relative orientations of the ego vehicle 641 and the second opposite direction vehicle 643. Similarly, the logic 113 may determine or confirm that the ego vehicle 641 and the first opposite direction vehicle 642 are traveling in opposite directions based on relative orientations of the ego vehicle 641 and the first opposite direction vehicle 642.

As illustrated in FIG. 6C, the logic 113 may generate, from the raw scenario data 638, or from a subset (e.g., all or a portion) thereof, processed scenario data 640 by generating and adding annotations to the raw scenario data 638. Alternatively, the logic 113 may directly obtain the processed scenario data 640. The processed scenario data 640 may include the same entities and same or similar annotations as in the processed scenario data 630. A relative position and/or orientation of the second opposite direction vehicle 643 may have changed in FIG. 6C compared to FIG. 6B.

Next, in FIG. 6D, from the processed scenario data 630 and/or 640, the logic 113 may generate one or more structured formats of the annotations by converting or reformatting the annotations. The structured formats may be hierarchical, and include statuses or states and activities of the ego vehicle 641, the first opposite direction vehicle 642, and the second opposite direction vehicle 643, which correspond to structured formats 670, 680, and 690, respectively. Here, the structured format 690 may indicate that a lateral activity of the second opposite direction vehicle 643 is swerving.

The logic 113 may, in conjunction with the machine learning components 111, infer and generate one or more descriptions or characterizations (hereinafter “descriptions”) of locomotive concepts encapsulated within the processed scenario data 630, 640 and/or the structured formats 670, 680, and 690. The logic 113 may generate a description 695 based on inferred intents of dynamic entities, as evidenced by changes in orientation of the second opposite direction vehicle 643 and/or a relative orientation of the second opposite direction vehicle 643 with respect to the lane 645, the opposite lane 646, the ego vehicle 641, and/or the first opposite direction vehicle 642. The description 695 indicates that a vehicle is swerving while approaching oncoming traffic.

The logic 113 may store or catalog, as scenario information, the processed scenario data 630 and/or 640, the structured formats 670, 680, and 690, the description 695, and/or the raw scenario data 628 and/or 638 together as one scenario within the database 130. In such a manner, the logic 113 may link or associate scenario information that was derived or generated from the raw scenario data 628 and/or 638. The logic 113 may further store, within the database 130, any simulation results or outputs from running or executing simulations from the scenario information. The scenario information may be searchable or retrievable. For example, if the logic 113 receives a query that is related to a potential locomotive concept or other concept captured by or inferred from the description 695, the processed scenario data 630 and/or 640, and/or the structured formats 670, 680, and 690, the logic 113 may output any of the scenario information. Such a query may refer to, for example, swerving, erratic behavior, or drunk driving.

The logic 113 may, from the scenario information or a portion thereof, predict one or more subsequent scenarios. For example, the logic 113 may predict that a subsequent scenario includes the ego vehicle 641 and/or the first opposite direction vehicle 642 yielding, slowing down, or pulling over to a side of a road in order to permit the second opposite direction vehicle 643 to pass.

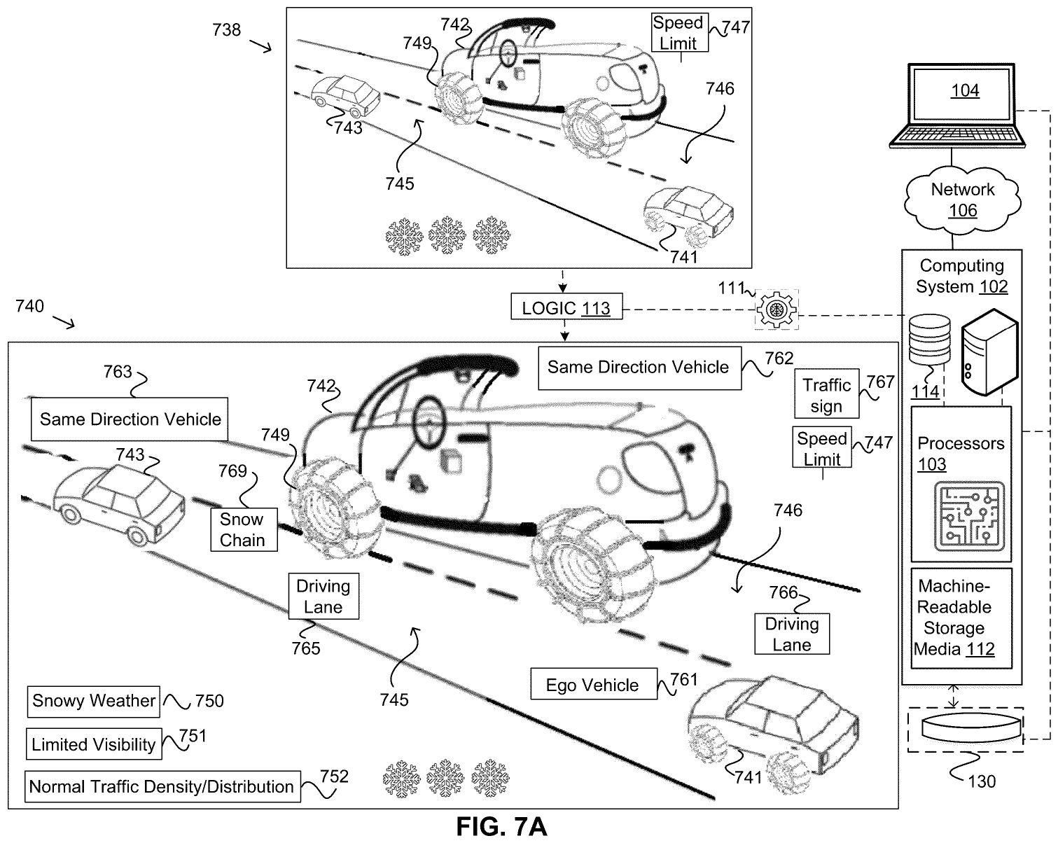

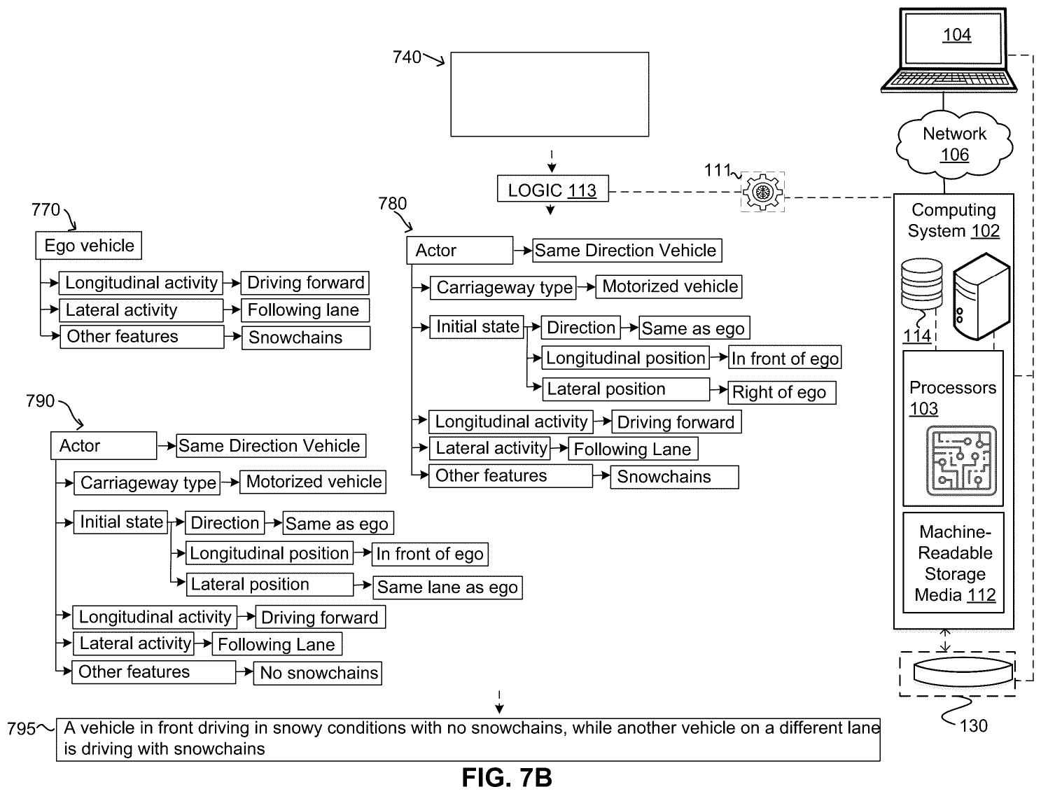

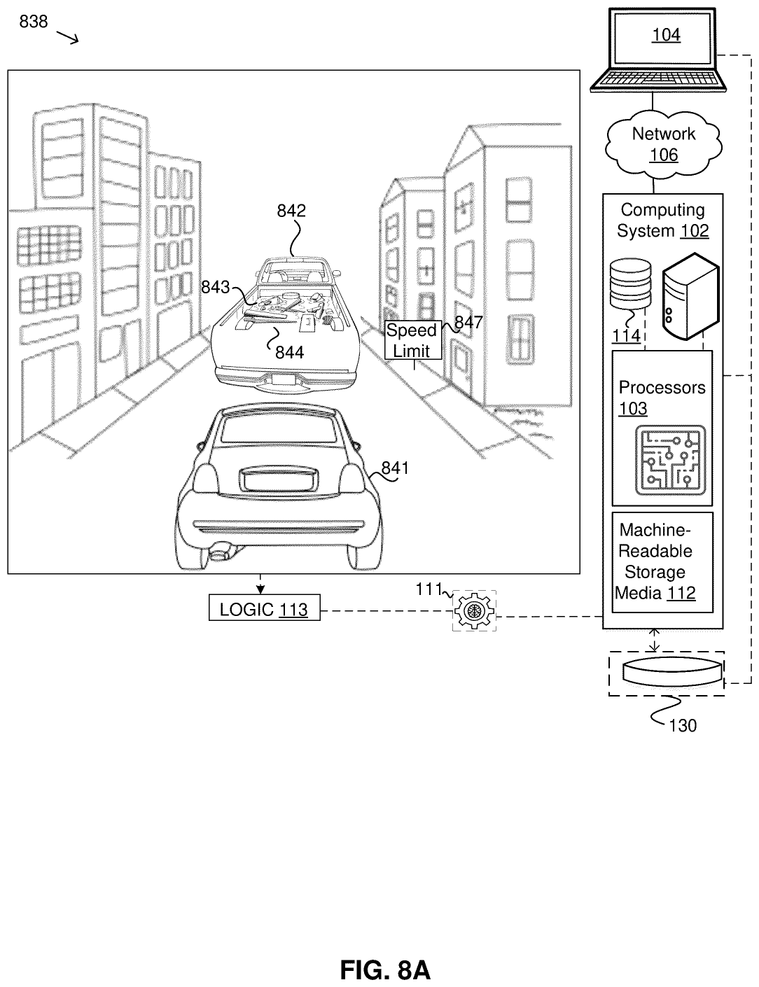

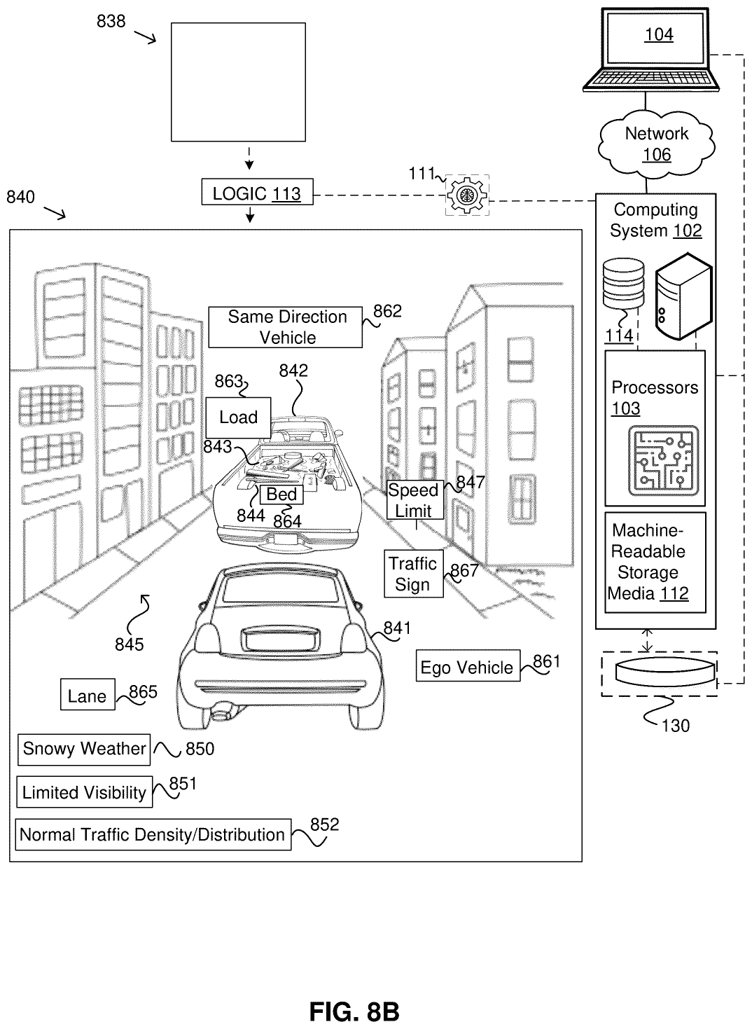

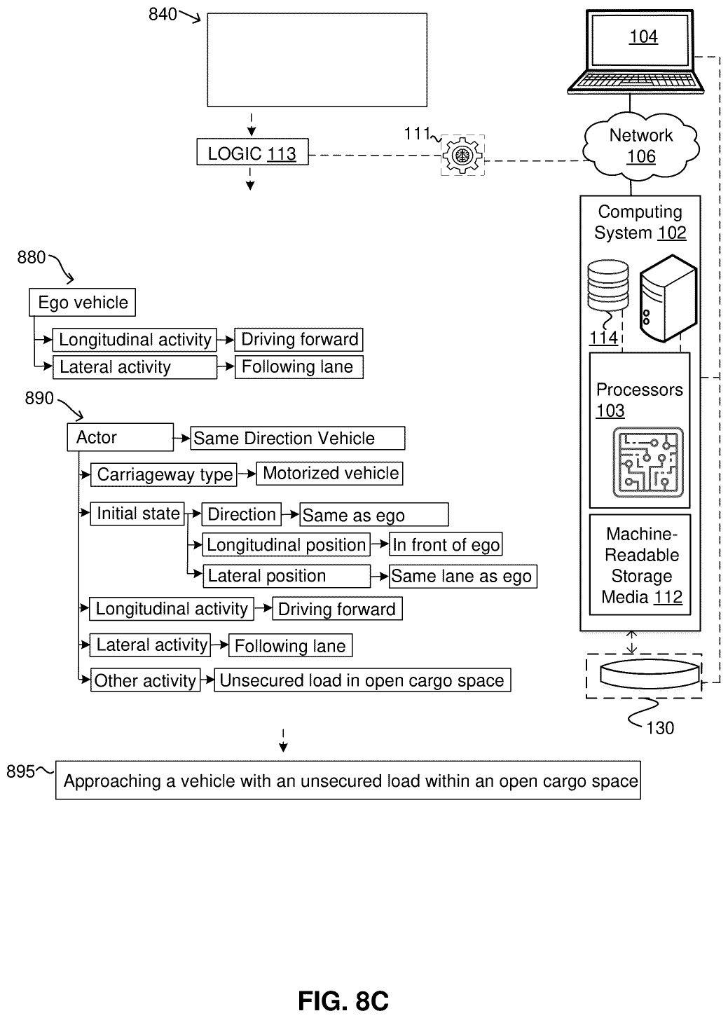

FIGS. 7A and 7B illustrate how a scenario may be characterized based on other features such as equipment, tools, instruments, devices, accessories and/or other additions (hereinafter “equipment”) attached to or associated with one or more dynamic entities, such as snow chains. Such a scenario is useful for simulation in order to identify potential danger which may not be salient. For example, if within a scenario, a first vehicle has snow chains and a second vehicle lacks snow chains in snowy conditions, then the logic 113 may infer that the second vehicle may have reduced traction and to navigate more carefully around the second vehicle as a result of the potentially increased danger of slip. For example, an ego vehicle 741 may have heightened alert and/or increased following distance in case the second vehicle has reduced traction and slips. Other examples of equipment or additions may include attached trailers and/or cargo or loads, such as on a back of a truck, as illustrated in FIGS. 8A-8C, which may indicate or suggest a potentially increased danger.

In FIG. 7A, the logic 113 may ingest, obtain, or derive raw scenario data 738. Here, in FIG. 7A, the raw scenario data 738 may be implemented in a similar manner as the raw scenario data 138, 238, 338, 438, 538, and/or 638, although content within the raw scenario data 738 is different and illustrates a different locomotive concept. Here, in FIG. 7A, the raw scenario data 738 may include the ego vehicle 741 on a lane 745, a first same direction vehicle 742 on a lane 746, and a second same direction vehicle 743 on the lane 745. The first same direction vehicle 742 may include snow chains 749, while the second same direction vehicle 743 may not include the snow chains 749. The ego vehicle 741 may also include snow chains. The raw scenario data 738 may further include a traffic sign 747.

The logic 113 may generate, from the raw scenario data 738 or from a subset (e.g., all or a portion) thereof, processed scenario data 740 by generating and adding annotations to the raw scenario data 738. Alternatively, the logic 113 may directly obtain the processed scenario data 740. The annotations may include or indicate dynamic entities and attributes thereof, static entities and attributes thereof, and/or environmental conditions. The annotations may include an annotation 761 indicating the ego vehicle 741, an annotation 765 indicating the lane 745, an annotation 762 indicating the first same direction vehicle 742, an annotation 766 indicating the lane 746, an annotation 763 indicating the second same direction vehicle 743, an annotation 767 indicating the traffic sign 747, and an annotation 769 indicating the snow chains 749. Annotations 750, 751, and 752 indicate that weather is snowy, limited in visibility, and that a traffic density or distribution is normal.

Next, in FIG. 7B, from the processed scenario data 740, the logic 113 may generate one or more structured formats of the annotations by converting or reformatting the annotations. The structured formats may be hierarchical, and include statuses or states and activities of the ego vehicle 741, the first same direction vehicle 742, and the second same direction vehicle 743, which correspond to structured formats 770, 780, and 790, respectively. The structured format 780 may indicate that the first same direction vehicle 742 has snow chains and the structured format 790 may indicate that the second same direction vehicle 743 is devoid of snow chains.

The logic 113 may, in conjunction with the machine learning components 111, infer and generate one or more descriptions or characterizations (hereinafter “descriptions”) of locomotive concepts encapsulated within the processed scenario data 740 and/or the structured formats 770, 780, and 790. The logic 113 may generate a description 795 based on statuses and/or equipment attached to other vehicles. The description 795 indicates that one vehicle is driving with snow chains and that another vehicle is devoid of snow chains.

The logic 113 may store or catalog, as scenario information, the processed scenario data 740, the structured formats 770, 780, and 790, the description 795, and/or the raw scenario data 738 together as one scenario within the database 130. In such a manner, the logic 113 may link or associate scenario information that was derived or generated from the raw scenario data 738, which facilitates retrieval of the scenario information. For example, if the logic 113 receives a query that is related to a potential locomotive concept or other concept captured by or inferred from the description 795, the processed scenario data 740 or the structured formats 770, 780, and 790, the logic 113 may output any of the scenario information. Such a query may be related to, for example, snow chains, snowy conditions, slippery conditions, slipping, high danger entities, and/or a larger following distance.

The logic 113 may, from the scenario information or a portion thereof, predict one or more subsequent scenarios. For example, the logic 113 may predict that a subsequent scenario includes the ego vehicle 741 and/or the first same direction vehicle 742 increasing a distance from the second same direction vehicle 743.

FIGS. 8A-8C illustrate how a scenario may be characterized based on other features such as a load carried by one or more dynamic entities. Such a scenario is useful for simulation in order to identify potential future danger or hazard. For example, if within a scenario, a vehicle is carrying a load attached to the vehicle, such as within a bed, and the bed is open, then the load may fall out of the bed which would trigger a hazard. An ego vehicle 841 may have heightened alert and/or increased following distance in case the load falls out of the bed.

In FIG. 8A, the logic 113 may ingest, obtain, or derive raw scenario data 838. Here, in FIG. 8A, the raw scenario data 838 may be implemented in a similar manner as the raw scenario data 138, 238, 338, 438, 538, 638, and/or 738 although content within the raw scenario data 838 is different and illustrates a different locomotive concept. Here, in FIG. 8A, the raw scenario data 838 may include the ego vehicle 841 on a lane 845, and a same direction vehicle 842 on the lane 845. The same direction vehicle 842 may include a load 843 within a bed, cargo, compartment, or a back portion (hereinafter “bed”) 844. The raw scenario data 838 may further include a traffic sign 847.

In FIG. 8B, the logic 113 may generate, from the raw scenario data 838 or from a subset (e.g., all or a portion) thereof, processed scenario data 840 by generating and adding annotations to the raw scenario data 838. Alternatively, the logic 113 may directly obtain the processed scenario data 840. The annotations may include or indicate dynamic entities and attributes thereof, static entities and attributes thereof, and/or environmental conditions. The annotations may include an annotation 861 indicating the ego vehicle 841, an annotation 865 indicating the lane 845, an annotation 862 indicating the same direction vehicle 842, an annotation 863 indicating the load 843, an annotation 864 indicating the bed 844, and an annotation 867 indicating the traffic sign 847. Annotations 850, 851, and 852 indicate that weather is snowy, limited in visibility, and that a traffic density or distribution is normal.

Next, in FIG. 8C, from the processed scenario data 840, the logic 113 may generate one or more structured formats of the annotations by converting or reformatting the annotations. The structured formats may be hierarchical, and include statuses or states and activities of the ego vehicle 841, and the same direction vehicle 842, which correspond to structured formats 880 and 890, respectively. The structured format 890 may indicate that the same direction vehicle 842 has an unsecured load in an open cargo space.

The logic 113 may, in conjunction with the machine learning components 111, infer and generate one or more descriptions or characterizations (hereinafter “descriptions”) of locomotive concepts encapsulated within the processed scenario data 840 and/or the structured formats 880 and 890. The logic 113 may generate a description 895 based on loads attached to other vehicles. The description 895 indicates that a vehicle has an unsecured load within an open cargo space.

The logic 113 may store or catalog, as scenario information, the processed scenario data 840, the structured formats 880 and 890, the description 895, and/or the raw scenario data 838 together as one scenario within the database 130. In such a manner, the logic 113 may link or associate scenario information that was derived or generated from the raw scenario data 838, which facilitates retrieval of the scenario information. For example, if the logic 113 receives a query that is related to a potential locomotive concept or other concept captured by or inferred from the description 895, the processed scenario data 840 or the structured formats 880 and 890, the logic 113 may output any of the scenario information. Such a query may be related to, for example, potential danger, an unsecured load, an open bed or cargo space, and/or a larger following distance.

The logic 113 may, from the scenario information or a portion thereof, predict one or more subsequent scenarios. For example, the logic 113 may predict that a subsequent scenario includes the ego vehicle 841 increasing a distance from the same direction vehicle 843.

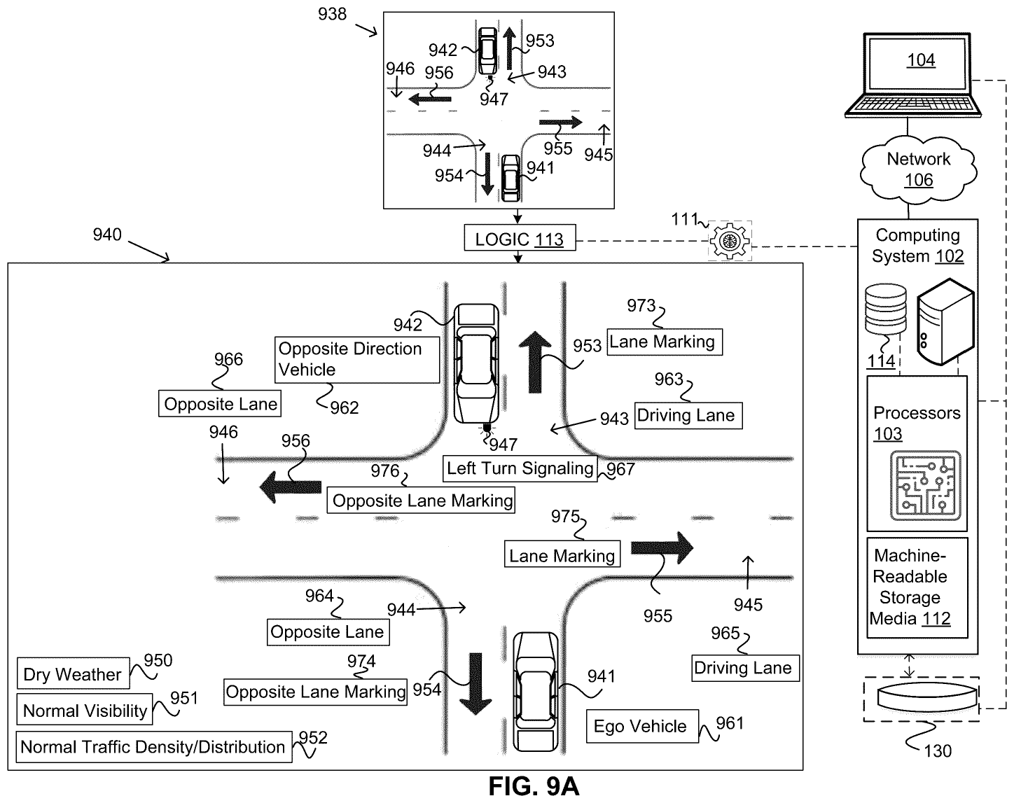

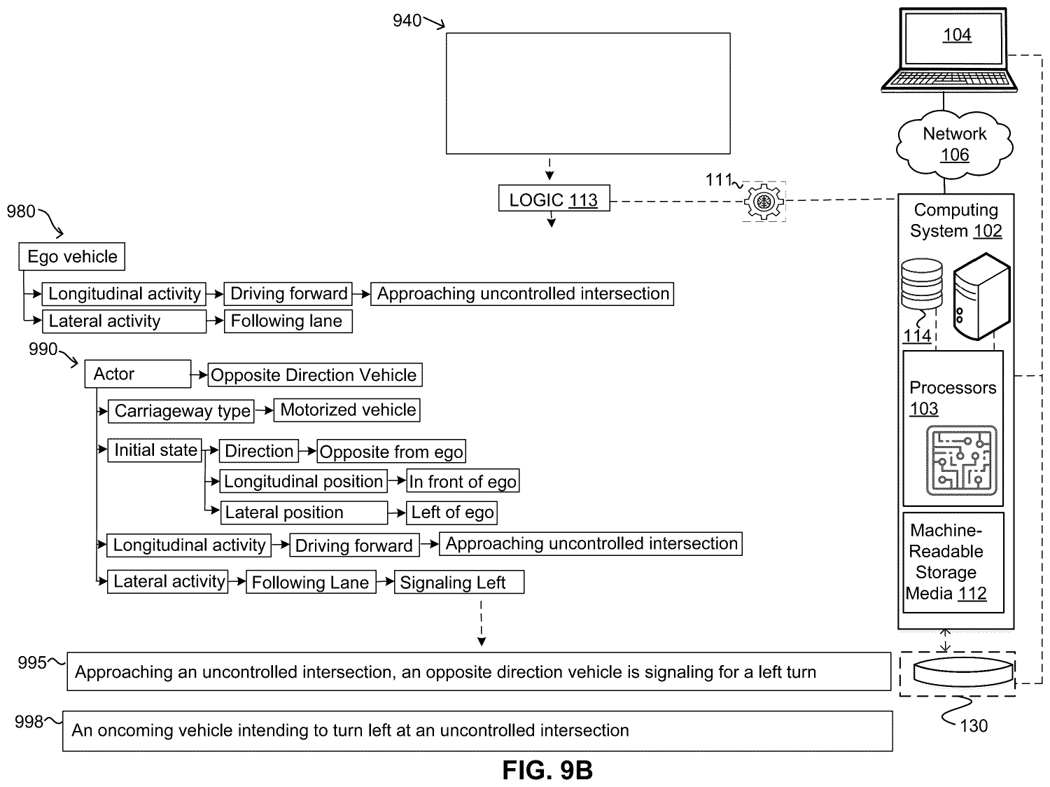

FIGS. 9A and 9B illustrate how a scenario may be characterized based on a road geometry, arrangement, layout, or organization (hereinafter “geometry”) such as an uncontrolled intersection. The scenario may additionally be characterized based on signaling. Such a scenario is useful for simulation in order to recognize possible dangers of a specific road geometry, and/or certain rules, practices, or guidelines of the specific road geometry, such as right-of way.

In FIG. 9A, the logic 113 may ingest, obtain, or derive raw scenario data 938. Here, in FIG. 9A, the raw scenario data 938 may be implemented in a similar manner as the raw scenario data 138, 238, 338, 438, 538, 638, 738, and/or 938, although content within the raw scenario data 938 is different and illustrates a different locomotive concept. Here, in FIG. 9A, the raw scenario data 938 may include an ego vehicle 941 on a lane 943 and an opposite direction vehicle 942 with a blinking left turn signal 947 and traveling on an opposite lane 944 that is in an opposite direction or orientation compared to the lane 943. The lane 943 may include a lane marking 953. The opposite lane 944 may include an opposite lane marking 954. A lane 945 may be orthogonal to the lane 943 and the opposite lane 944. The lane 945 may include a lane marking 955. An opposite lane 946 may be in an opposite direction or opposite orientation relative to the lane 945. The opposite lane 946 may include an opposite lane marking 956.

The logic 113 may generate, from the raw scenario data 938 or from a subset (e.g., all or a portion) thereof, processed scenario data 940 by generating and adding annotations to the raw scenario data 938. Alternatively, the logic 113 may directly obtain the processed scenario data 940. The annotations may include or indicate dynamic entities and attributes thereof, static entities and attributes thereof, and/or environmental conditions. The annotations may include an annotation 961 indicating the ego vehicle 941, an annotation 962 indicating the opposite direction vehicle 942, an annotation 963 indicating the lane 943, an annotation 964 indicating the opposite lane 944, an annotation 965 indicating the lane 945, an annotation 966 indicating the opposite lane 946, an annotation 967 indicating the blinking left turn signal 947, an annotation 973 indicating the lane marking 953, an annotation 974 indicating the opposite lane marking 954, an annotation 975 indicating the lane 955, and an annotation 976 indicating the opposite lane marking 956. Annotations 950, 951, and 952 may further indicate environmental conditions including an indication of dry weather, normal visibility, and normal traffic density or distribution.

Next, in FIG. 9B, from the processed scenario data 940, the logic 113 may generate one or more structured formats of the annotations by converting or reformatting the annotations. The structured formats may be hierarchical, and include statuses or states and activities of the ego vehicle 941, and the opposite direction vehicle 942, which correspond to structured formats 980 and 990, respectively. The structured format 780 may indicate that the ego vehicle 941 and the opposite direction vehicle 942 are both approaching an uncontrolled intersection, and the opposite direction vehicle 942 is signaling for a left turn.

The logic 113 may, in conjunction with the machine learning components 111, infer and generate one or more descriptions or characterizations (hereinafter “descriptions”) of locomotive concepts encapsulated within the processed scenario data 940 and/or the structured formats 980, and 990. The logic 113 may generate descriptions 995 and 998 based on statuses and/or equipment attached to other vehicles. The descriptions 995 and 998 indicate an approaching uncontrolled intersection in which a vehicle from an opposite direction has signaled or indicated an intent to turn left.

The logic 113 may store or catalog, as scenario information, the processed scenario data 940, the structured formats 980 and 990, the description 995, and/or the raw scenario data 938 together as one scenario within the database 130. In such a manner, the logic 113 may link or associate scenario information that was derived or generated from the raw scenario data 938, which facilitates retrieval of the scenario information. For example, if the logic 113 receives a query that is related to a potential locomotive concept or other concept captured by or inferred from the descriptions 995 and/or 998, the processed scenario data 940 or the structured formats 980, and 990, the logic 113 may output any of the scenario information. Such a query may be related to, for example, an uncontrolled intersection, an intersection with no traffic lights, a right of way at an intersection, and/or signaling at an intersection.

The logic 113 may, from the scenario information or a portion thereof, predict one or more subsequent scenarios. For example, the logic 113 may predict that a subsequent scenario includes depending on relative positions of the ego vehicle 941 and the opposite direction vehicle 942, or distances from the uncontrolled intersection, the ego vehicle 941 either slowing down to permit the opposite direction vehicle 942 to turn, the ego vehicle 941 proceeding through the uncontrolled intersection, or the ego vehicle 941 turning left or right at the uncontrolled intersection.

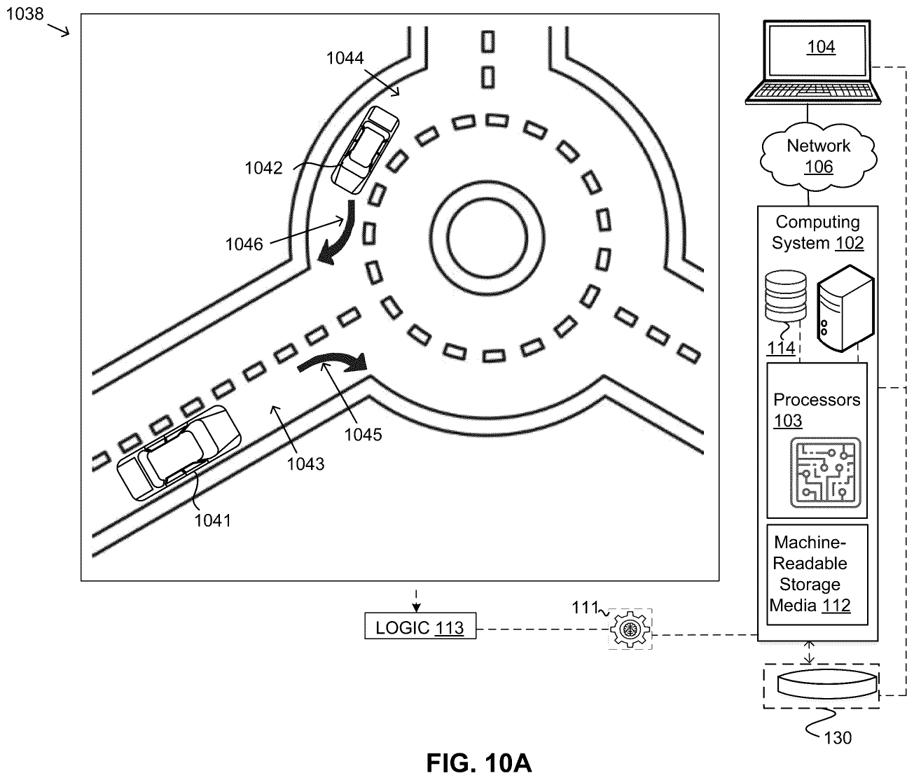

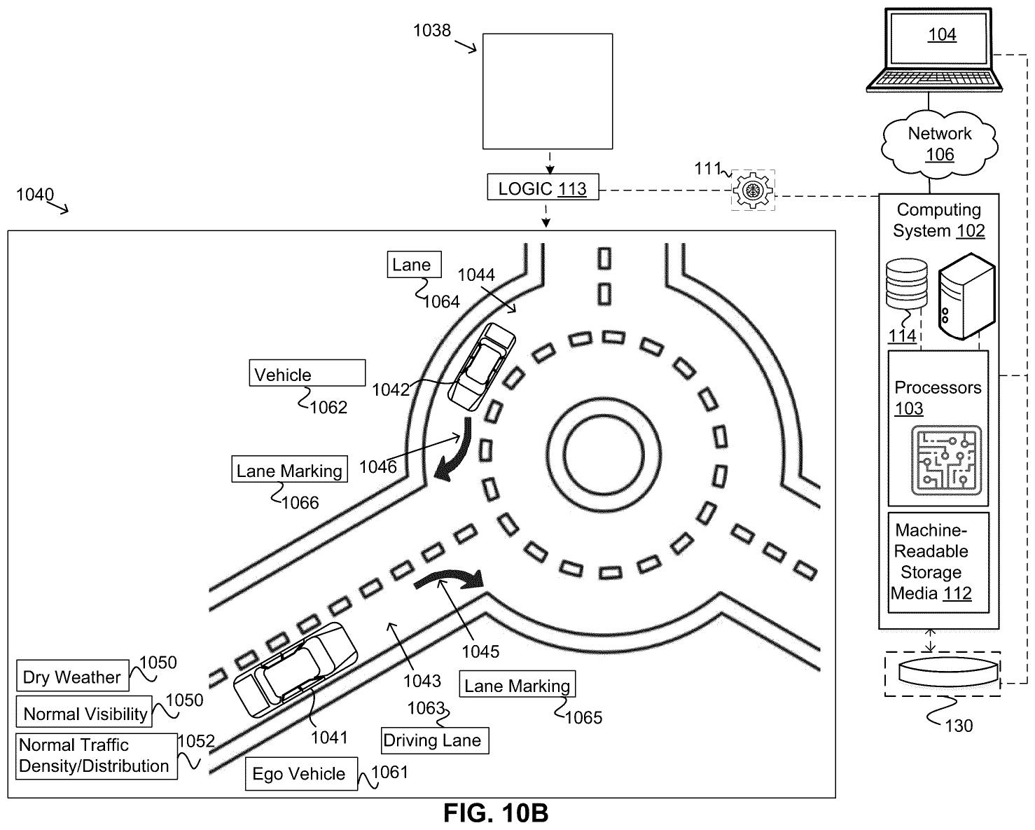

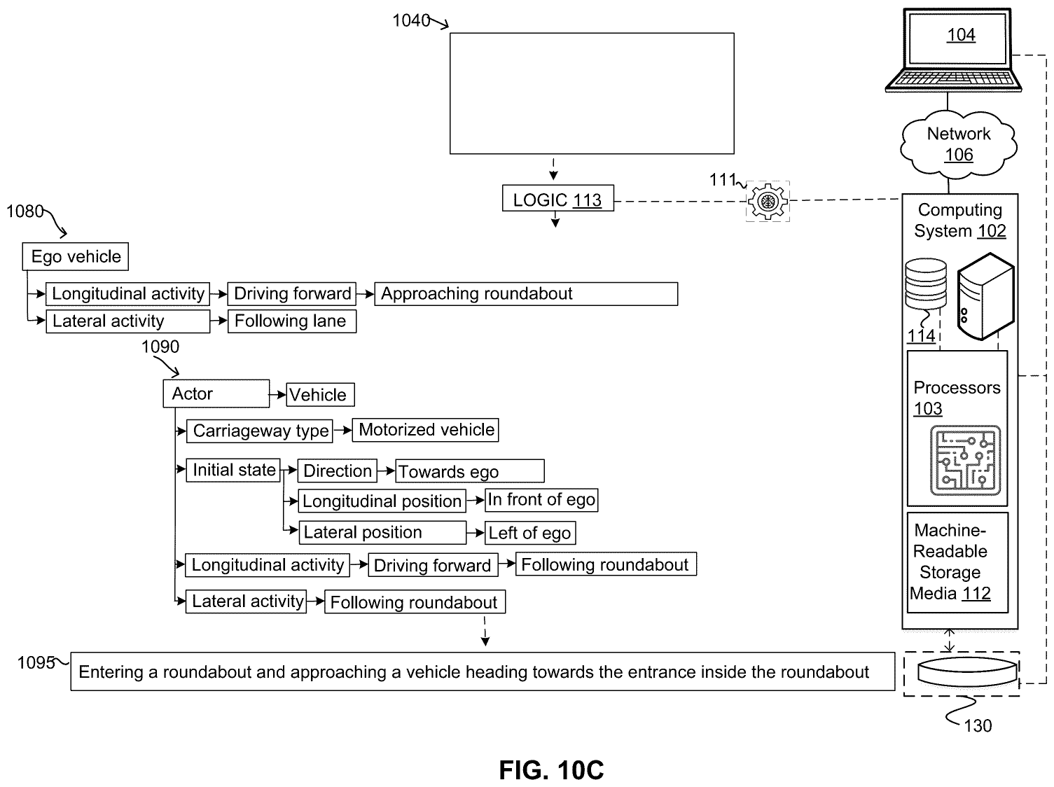

FIGS. 10A, 10B, and 10C illustrate how a scenario may be characterized based on a road geometry, such as a roundabout. In FIG. 10A, the logic 113 may ingest, obtain, or derive raw scenario data 1038. The raw scenario data 1038 may be implemented in a similar manner as the raw scenario data 138, 238, 338, 438, 538, 638, 738, 838, and/or 938, although content within the raw scenario data 1038 is different and illustrates a different locomotive concept. Here, in FIG. 10A, the raw scenario data 1038 may include an ego vehicle 1041 on a lane 1043, a vehicle 1042 on lane 1044, a marking 1045 indicating a permitted turn direction, and a marking 1046 indicating a permitted turn direction.

In FIG. 10B, the logic 113 may generate, from the raw scenario data 1038 or from a subset (e.g., all or a portion) thereof, processed scenario data 1040 by generating and adding annotations to the raw scenario data 1038. Alternatively, the logic 113 may directly obtain the processed scenario data 1040. The annotations may include or indicate dynamic entities and attributes thereof, static entities and attributes thereof, and/or environmental conditions. For example, the annotations may include an annotation 1061 indicating the ego vehicle 1041, an annotation 1062 indicating the vehicle 1042, an annotation 1063 indicating the lane 1043, an annotation 1064 indicating the lane 1044, an annotation 1065 indicating the marking 1045, and an annotation 1066 indicating the marking 1046. Annotations 1050, 1051, and 1052 may further indicate environmental conditions including an indication of dry weather, normal visibility, and normal traffic density or distribution.

Next, in FIG. 10C, from the processed scenario data 1040, the logic 113 may generate one or more structured formats of the annotations by converting or reformatting the annotations. The structured formats may be hierarchical, and include statuses or states and activities of the ego vehicle 1041, and the vehicle 1042, which correspond to structured formats 1080 and 1090, respectively. Here, the structured format 1080 indicates that the ego vehicle 1041 is approaching a roundabout while the structured format 1090 indicates that the vehicle 1042 is currently inside and following the roundabout.

The logic 113 may, in conjunction with the machine learning components 111, infer and generate one or more descriptions or characterizations (hereinafter “descriptions”) of locomotive concepts encapsulated within the processed scenario data 1040 and/or the structured formats 1080 and 1090. The logic 113 may generate a description 1095 that indicates an approaching roundabout and that a vehicle is currently inside the roundabout and approaching the entrance of the roundabout.

The logic 113 may store or catalog, as scenario information, the processed scenario data 1040, the structured formats 1080, and 1090, the description 1095, and/or the raw scenario data 1038 together as one scenario within the database 130. In such a manner, the logic 113 may link or associate scenario information that was derived or generated from the raw scenario data 1038, which facilitates retrieval of the scenario information. For example, if the logic 113 receives a query that is related to a potential locomotive concept or other concept captured by or inferred from the description 1095, the processed scenario data 1040 or the structured formats 1080 and 1090, the logic 113 may output any of the scenario information. Such a query may relate to a roundabout, rotary or traffic circle, intersection, junction, right of way, or priority.

The logic 113 may, from the scenario information or a portion thereof, predict one or more subsequent scenarios. For example, the logic 113 may predict that a subsequent scenario includes the ego vehicle 1041 waiting for the vehicle 1042 to proceed or to turn before entering the roundabout.

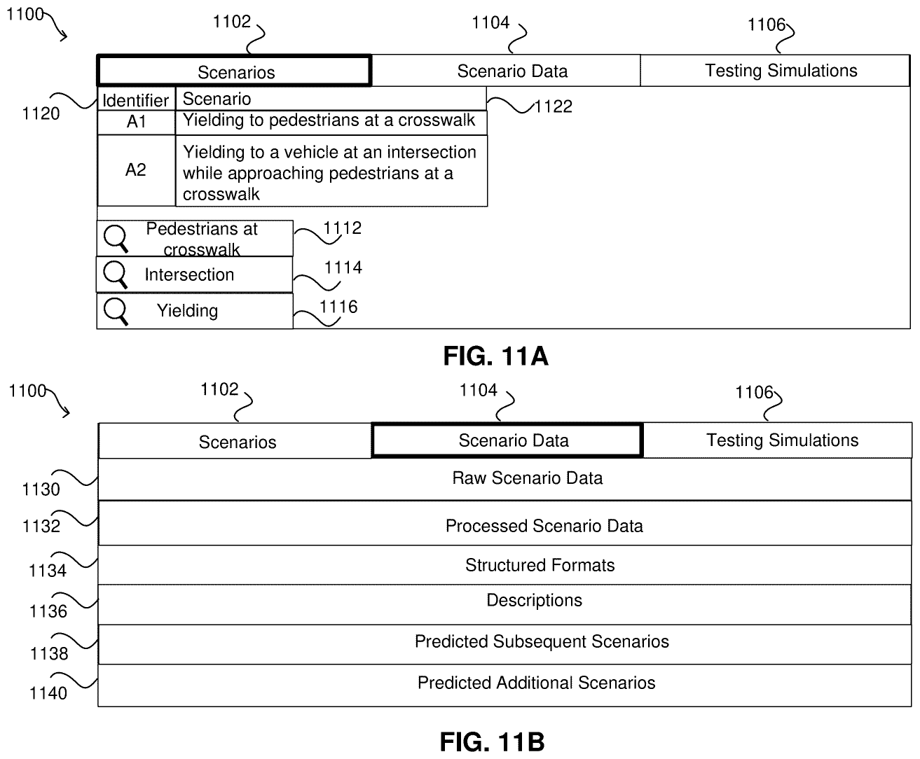

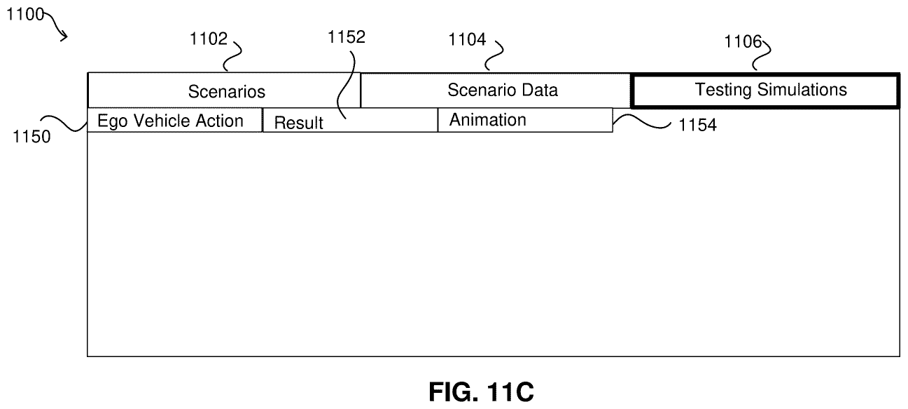

FIGS. 11A, 11B, and 11C illustrate an example interface or window (hereinafter “interface”), such as a display interface or a graphical user interface (GUI) through which scenario information may be retrieved and/or presented. In FIG. 11A, an interface 1100 may be generated by the logic 113 and may include tabs such as a scenarios tab 1102, a scenario data tab 1104, and a testing simulations tab 1106. Upon selection, the scenarios tab 1102 may include one or more search bars at which one or more searches 1112, 1114, and/or 1116, which define search criteria, are inputted or received. The scenarios tab 1102 may further present one or more matches, results, hits, or potential matches to the searches 1112, 1114, and 1116. For example, the logic 113 may present one or more identifiers 1120 and summaries or synopses 1122 of matching or potentially matching scenarios. The summaries 1122 may include the previously alluded to descriptions (e.g., the descriptions 195, 198, 295, 298, 395, 495, 595, 695, 795, 895, 995, and/or 1095), and/or alternative or condensed versions of the descriptions.

Meanwhile, in FIG. 11B, upon a selection of the scenario data tab 1104, the logic 113 may present any of the aforementioned raw scenario data 1130 (e.g., the raw scenario data 138, 238, 338, 438, 538, 628, 638, 738, 838, 938, and/or 1038), the processed scenario data 1132 (e.g., the processed scenario data 140, 240, 340, 440, 540, 630, 640, 740, 840, 940 and/or 1040), one or more structured formats 1134 (e.g., the structured formats 180, 190, 270, 280, 290, 370, 380, 390, 480, 580, 670, 680, 690, 770, 780, 790, 880, 890, 980, 990, 1080, and/or 1090), one or more descriptions 1136 (e.g., the descriptions 195, 198, 295, 298, 395, 495, 595, 695, 795, 895, 995, and/or 1095), one or more predicted subsequent scenarios 1138, and/or one or more predicted additional scenarios 1140, as described previously, which may be related to the scenario. For example, if a current scenario includes a right turn, then a predicted additional scenario may include a left turn.

Meanwhile, in FIG. 11C, upon a selection of the testing simulations tab 1106, the logic 113 may present any information or data related to a simulation that was run on a scenario. For example, this information may include different ego vehicle actions 1150, such as yielding, pulling over, or speeding, one or more results 1152 following the ego vehicle actions, and/or one or more animations 1154 of the one or more results. The animations may include a media output such as a video file.

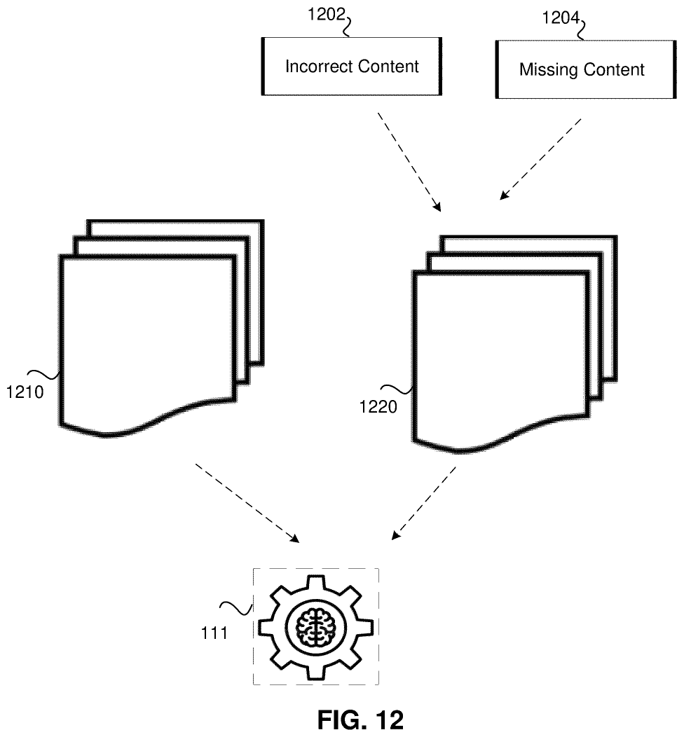

FIG. 12 describes an iterative and/or sequential training process of the machine learning components 111, which may be continuously trained to perform any of the functions described above, including processing raw scenario data such as generating descriptions, predicting subsequent scenarios, generating new scenarios, and/or retrieving scenarios. For example, as new driving data or scenario data is generated or obtained, the machine learning components 111 may be continuously trained. The training may be performed in part by the computing system 102 and/or by a different computing system. For example, the machine learning components 111 may be initially trained using a first training dataset 1210, and subsequently trained using a second training dataset 1220. The first training dataset 1210 may include examples of appropriate characterizations, such as generating descriptions, for a given scenario, which may encompass proper content and/or syntax of the descriptions. The first training dataset 1210 may additionally include inappropriate annotations so that after training, the machine learning components 111 may be programmed to avoid pitfalls. The second training dataset 1220 may include compiled examples, which may encompass, or be generated based on, incorrectly characterized scenarios by the machine learning components 111. The compiled examples may be corrected based on the incorrectly characterized scenarios. For example, training using the second training dataset 1220 may occur following a set of inferences which were made at least partially incorrectly by the machine learning components 111. Such incorrect inferences may be attributed to any of incorrect recognition and/or incorrect translation or processing of data such as media or text, incorrectly weighing of criteria, and/or incorrect assumptions. The second training dataset 1220 may include and/or be generated based on corrections from examples 1202 and 1204. The examples 1202 may encompass incorrectly inferred characterizations, which may include false positive characterizations. For instance, the examples 1202 may include inferences of an existence of an entity, condition, or action (e.g., overtaking, turning) that did not actually exist or happen. Meanwhile, the examples 1204 may encompass those having missing characterizations, which may include false negative characterizations. For instance, the examples 1204 may have missed an inference of an entity, condition, or action that actually occurred within a scenario. The machine learning components 111 may be trained to perform other functions such as predicting subsequent and/or new scenarios in a same iterative manner as described above.

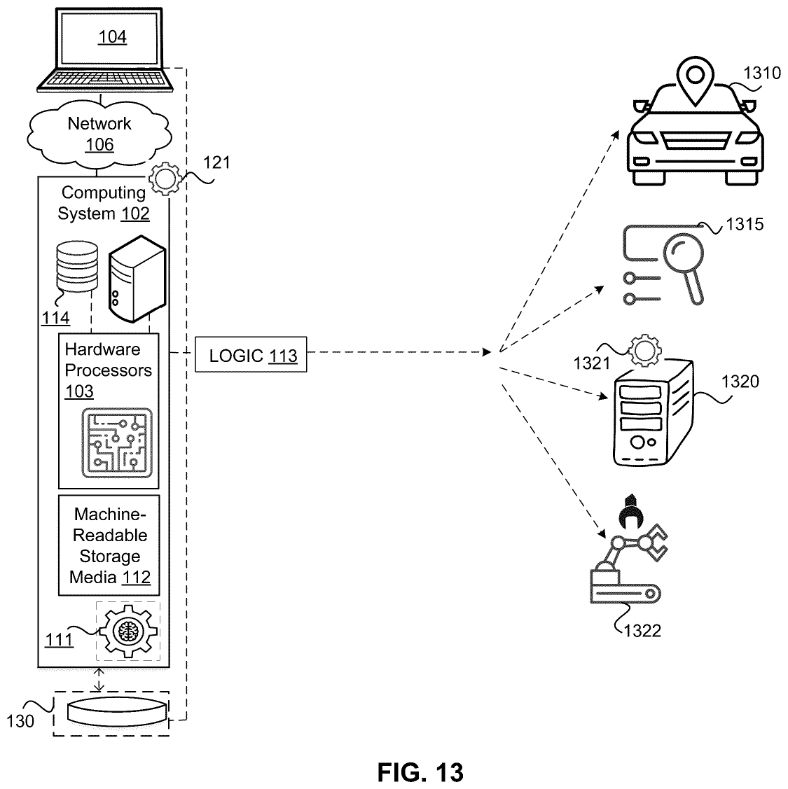

FIG. 13 illustrates that as a result of training the machine learning components 111, certain downstream actions may be triggered, as part of a workflow or a process. The computing system 102 and/or a different computing system may implement a testing simulation based on the processing of each scenario. The testing simulation includes executing of a test driving operation involving a test vehicle and monitoring one or more results, statistics and test vehicle attributes of the test vehicle. The results may indicate, for different test vehicle actions, occurrences that followed (e.g., disengagement, accident, safe maneuvering). The statistics may include, monitoring crash rate distributions, crash type distributions, severity distributions, post-encroachment time distributions, and/or near-miss distributions. In some examples, the test vehicle may include, or be, an ego vehicle.

Specifically, the testing simulation may encompass performing navigation 1310, additional monitoring 1315, transmitting and/or writing information to a different computing system 1320, for example, via an API 1321, and/or maintenance or other physical operations 1322 such as adjusting a physical or electronic infrastructure of a vehicle in order to better react to certain safety conditions. These operations may be part of a process of conducting simulations.

As an example of the additional monitoring 1315, during a simulation using a scenario, the computing system 102 and/or a different computing system may monitor the aforementioned statistics and vehicle parameters such as engine operation parameters (e.g., engine rotation rate), moment of inertia, and/or position of center of gravity, to ensure safe operation of a vehicle, in particular, to verify whether attributes or parameters of a vehicle fall within certain operating ranges or thresholds. In some examples, the additional monitoring 1315 may occur in response to certain attributes or parameters falling outside of certain operating ranges or thresholds. This monitoring or recording of other entity types may be performed by the computing system 102, or may be delegated to a different processor. In other examples, a downstream action may include the writing of information 1320. Such writing of information may encompass transmission or presentation of information, an alert, and/or a notification to the computing device 104 and/or to other devices. The information may include indications of which attributes or parameters of a vehicle may fall outside of operating ranges or thresholds, or reasons that an alert was triggered, and/or one or more timestamps corresponding to an originating or creation time of underlying data that caused the triggering of the alert. Alternatively, an alert may be triggered using a predicted time at which an attribute or parameter may be predicted to fall outside of an operating range or threshold.

In yet other examples, a downstream action may entail an applications programming interface (API) 121 of the computing system 102 interfacing with or calling the API 1321 of the different computing system 1320. For example, the different computing system 1320 may perform analysis and/or transformation or modification of data, through some electronic or physical operation. Meanwhile, the physical operations 1322 may include controlling braking, steering, and/or throttle components to effectuate a throttle response, a braking action, and/or a steering action during navigation.

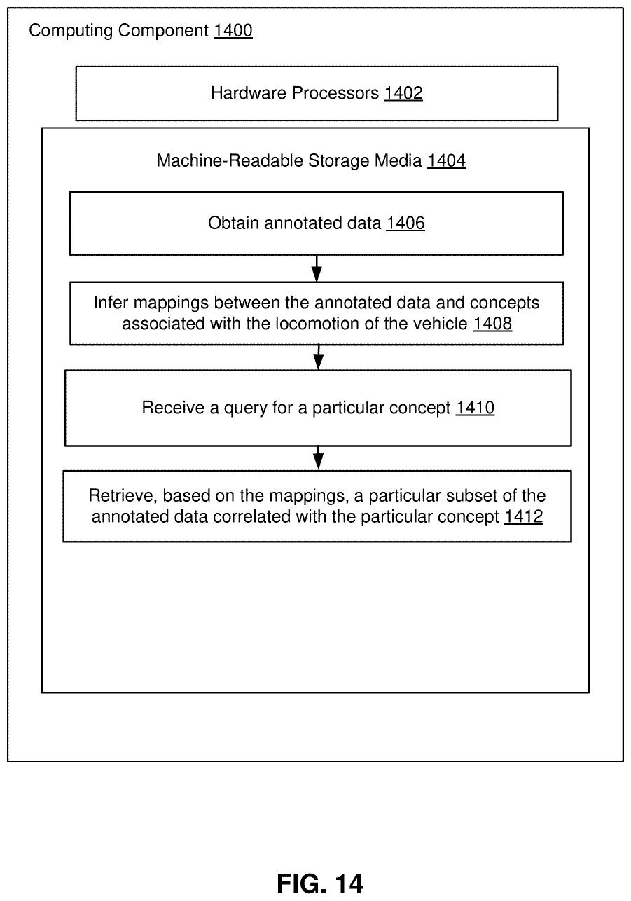

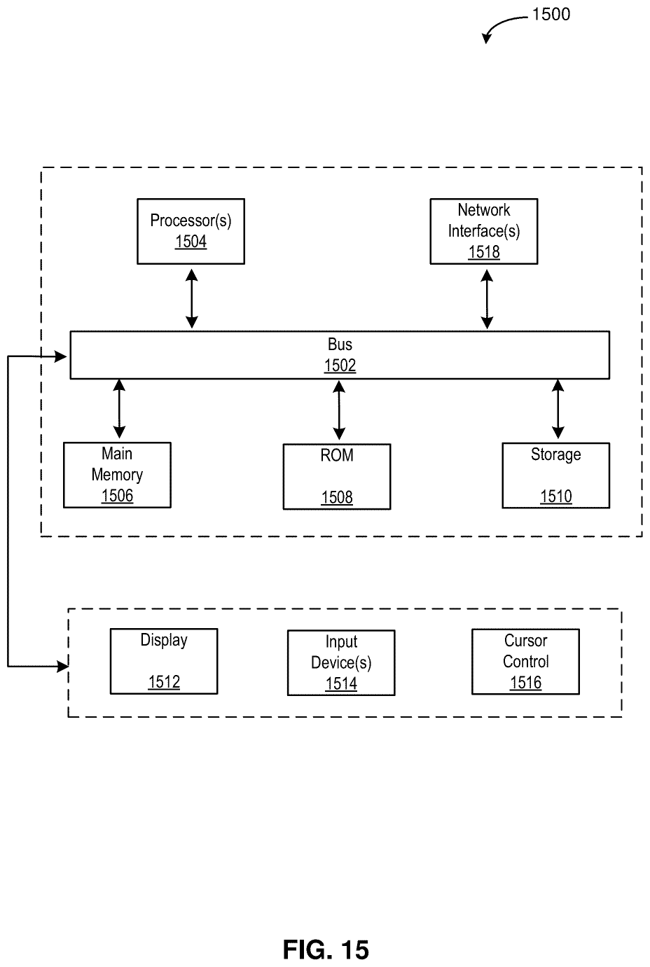

FIG. 14 illustrates a computing component 1400 that includes one or more hardware or other processors 1402 and machine-readable storage media 1404 storing a set of machine-readable/machine-executable instructions that, when executed, cause the processor(s) 1402 to perform an illustrative method of characterizing and retrieving processed scenario data from raw scenario data. The computing component 1400 may be implemented as the computing system 102 of FIG. 1. The processors 1402 may be implemented as the processors 103. The machine-readable storage media 1404 may be implemented as the machine-readable storage media 112, and may include suitable machine-readable storage media described in FIG. 15.

At step 1406, the processors 1402 may execute machine-readable/machine-executable instructions stored in the machine-readable storage media 1404 to obtain or generate annotated data (e.g., the processed scenario data 140, 240, 340, 440, 540, 630, 640, 740, 840, 940 and/or 1040) of or related to a scenario. In some examples, the annotated data may include annotated media frames. The annotated data may be directly obtained, for example, from a storage (e.g., the database 140 of the computing system 102) or from an external source. Alternatively, the annotated data may be generated from raw data (e.g., the raw scenario data 138, 238, 338, 438, 538, 628, 638, 738, 838, 938, and/or 1038). The annotations may include dynamic entities and attributes thereof, static entities and attributes thereof, and/or environmental conditions.

At step 1408, the processors 1402 may execute machine-readable/machine-executable instructions stored in the machine-readable storage media 1404 to infer mappings or connections between the annotated data and concepts associated with the locomotion of the vehicle. For example, the inferring of the mappings may encompass generating one or more structured formats (e.g., the structured formats 180, 190, 270, 280, 290, 370, 380, 390, 480, 580, 670, 680, 690, 770, 780, 790, 880, 890, 980, 990, 1080, and/or 1090) which manifest the annotated data according to a different structure. From the structured formats, the processors 1402 may generate one or more descriptions (e.g., the descriptions 195, 198, 295, 298, 395, 495, 595, 695, 795, 895, 995, and/or 1095) to characterize a scenario. The descriptions may include a natural language syntax that covers one or more locomotive concepts within the scenario, such as yielding, overtaking, right of way, jaywalking, or dangerous driving. The inferred mappings may consolidate the annotated data with the mapped concepts. The consolidated annotated data and the mapped concepts may be organized, catalogued, and/or index for storage, for example, within the database 140. Thus, the consolidated annotated data and the mapped concepts may be retrieved and/or accessed upon the processors 1402 receiving a query. The mapped concepts may include or be based on inferred vehicle intents, signaling, vehicle types (e.g., authority vehicles, non-terrestrial vehicles), non-vehicular entities, equipment on vehicles, and/or road geometry. In some examples, the processors 1402 may further map the annotated data to a danger level, such as a probability of disengagement, in order to identify certain combinations of annotations that correspond to a high probability of disengagements (e.g., above a threshold probability, such as 25 percent, 50 percent, 75 percent or any applicable percentage). The processors 1402 may flag those combinations of annotations that correspond to a probability exceeding the threshold probability of disengagements.

At step 1410, the processors 1410 may execute machine-readable/machine-executable instructions stored in the machine-readable storage media 1404 to receive a query for one or more particular concepts. At step 1412, the processors 1412 may retrieve, based on the consolidated annotated data and the mapped concepts, a particular subset of the annotated data and/or any stored data (e.g., raw scenario data, processed scenario data, structured formats, and/or descriptions) associated with a scenario and correlated or mapped to the particular concept.

The techniques described herein, for example, are implemented by one or more special-purpose computing devices. The special-purpose computing devices may be hard-wired to perform the techniques, or may include circuitry or digital electronic devices such as one or more application-specific integrated circuits (ASICs) or field programmable gate arrays (FPGAs) that are persistently programmed to perform the techniques, or may include one or more hardware processors programmed to perform the techniques pursuant to program instructions in firmware, memory, other storage, or a combination.

FIG. 15 illustrates a block diagram of a computer system 1500 upon which any of the embodiments described herein may be implemented. The computer system 1500 includes a bus 1502 or other communication mechanism for communicating information, one or more hardware or other processors, such as cloud processors, 1504 coupled with bus 1502 for processing information. A description that a device performs a task is intended to mean that one or more of the processor(s) 1504 performs.

The computer system 1500 also includes a main memory 1506, such as a random access memory (RAM), cache and/or other dynamic storage devices, coupled to bus 1502 for storing information and instructions to be executed by processor 1504. Main memory 1506 also may be used for storing temporary variables or other intermediate information during execution of instructions to be executed by processor 1504. Such instructions, when stored in storage media accessible to processor 1504, render computer system 1500 into a special-purpose machine that is customized to perform the operations specified in the instructions.

The computer system 1500 further includes a read only memory (ROM) 1508 or other static storage device coupled to bus 1502 for storing static information and instructions for processor 1504. A storage device 1510, such as a magnetic disk, optical disk, or USB thumb drive (Flash drive), etc., is provided and coupled to bus 1502 for storing information and instructions.

The computer system 1500 may be coupled via bus 1502 to output device(s) 1512, such as a cathode ray tube (CRT) or LCD display (or touch screen), for displaying information to a computer user. Input device(s) 1514, including alphanumeric and other keys, are coupled to bus 1502 for communicating information and command selections to processor 1504. Another type of user input device is cursor control 1516. The computer system 1500 also includes a communication interface 1518 coupled to bus 1502.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise. The phrases “at least one of,” “at least one selected from the group of,” or “at least one selected from the group consisting of,” and the like are to be interpreted in the disjunctive (e.g., not to be interpreted as at least one of A and at least one of B).

Reference throughout this specification to “one embodiment” or “an embodiment” means that a particular feature, structure or characteristic described in connection with the embodiment is included in at least one embodiment of the present invention. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiment.

A component being implemented as another component may be construed as the component being operated in a same or similar manner as the another component, and/or comprising same or similar features, characteristics, and parameters as the another component.

1. A system comprising:
one or more processors; and
a memory storing instructions that, when executed by the one or more processors, cause the system to perform:
obtaining or generating annotated data, wherein the annotated data comprises annotations and are associated with locomotion of a vehicle;
inferring mappings between the annotated data and concepts associated with the locomotion of the vehicle, wherein each of the mappings correlates a subset of the annotated data with a concept;
receiving a query for a particular concept; and
retrieving, based on the mappings, a particular subset of the annotated data correlated with the particular concept.

2. The system of claim 1, wherein the annotations are associated with at least one or more static entities, one or more dynamic entities, or one or more environmental conditions.

3. The system of claim 2, wherein the one or more dynamic entities comprise the vehicle or one or more other vehicles.

4. The system of claim 1, wherein the particular subset of the annotated data comprises a first frame and a second frame, the second frame comprising a static entity or a dynamic entity that is absent from the first frame, wherein the first frame and the second frame comprise media frames.

5. The system of claim 1, wherein the inferring of the mappings is based on relative positions between the annotations in a media frame.

6. The system of claim 1, wherein the inferring of the mappings is based on relative orientations between the annotations in a media frame.

7. The system of claim 1, wherein the inferring of the mappings is based on a signal of the vehicle or of an other vehicle.

8. The system of claim 1, wherein the inferring of the mappings is performed by a machine learning component, the machine learning component being trained over two stages, wherein a first stage is based on a first training dataset that correlates hypothetical annotated data to hypothetical concepts and a second stage is based on a second training dataset that comprises corrected hypothetical annotated data correlated to corrected hypothetical concepts.

9. The system of claim 1, wherein the annotated data comprises media files.

10. The system of claim 1, wherein the instructions further cause the system to perform:
executing a testing simulation based on the inferred mappings, wherein the testing simulation comprises executing of a test driving operation involving a test vehicle that corresponds to the vehicle and monitoring one or more test vehicle attributes of the test vehicle.

11. A method comprising:
obtaining or generating annotated data, wherein the annotated data comprises annotations and are associated with locomotion of a vehicle;
inferring mappings between the annotated data and concepts associated with the locomotion of the vehicle, wherein each of the mappings correlates a subset of the annotated data with a concept;
receiving a query for a particular concept; and
retrieving, based on the mappings, a particular subset of the annotated data correlated with the particular concept.

12. The method of claim 11, wherein the annotations are associated with at least one or more static entities, one or more dynamic entities, or one or more environmental conditions.

13. The method of claim 12, wherein the one or more dynamic entities comprise the vehicle or one or more other vehicles.

14. The method of claim 11, wherein the particular subset of the annotated data comprises a first frame and a second frame, the second frame comprising a static entity or a dynamic entity that is absent from the first frame, wherein the first frame and the second frame comprise media frames.

15. The method of claim 11, wherein the inferring of the mappings is based on relative positions between the annotations in a media frame.

16. The method of claim 11, wherein the inferring of the mappings is based on relative orientations between the annotations in a media frame.

17. The method of claim 11, wherein the inferring of the mappings is based on a signal of the vehicle or of an other vehicle.

18. The method of claim 11, wherein the inferring of the mappings is performed by a machine learning component, the machine learning component being trained over two stages, wherein a first stage is based on a first training dataset that correlates hypothetical annotated data to hypothetical concepts and a second stage is based on a second training dataset that comprises corrected hypothetical annotated data correlated to corrected hypothetical concepts.

19. The method of claim 11, wherein the annotated data comprises media files.

20. The method of claim 11, further comprising:
executing a testing simulation based on the inferred mappings, wherein the testing simulation comprises executing of a test driving operation involving a test vehicle that corresponds to the vehicle and monitoring one or more test vehicle attributes of the test vehicle.
